(19) United States
(12) Patent Application Publication
(10) Pub. No.: US 2026/0101808 A1
(43) Pub. Date: Apr. 9, 2026

(54) SEMICONDUCTOR DEVICE AND SEMICONDUCTOR MODULE

(71) Applicant: Nuvoton Technology Corporation Japan, Kyoto (JP)

(72) Inventors: Masahide TAGUCHI, Kyoto (JP); Takashi YUI, Kyoto (JP)

(21) Appl. No.: 19/388,416

(22) Filed: Nov. 13, 2025

Related U.S. Application Data
(63) Continuation of application No. PCT/JP2024/035507, filed on Oct. 3, 2024.
(60) Provisional application No. 63/614,845, filed on Dec. 26, 2023.

(51) Int. Cl. H01L 23/00; H01L 23/31

(52) U.S. Cl. CPC H10W 74/137; H10W 72/223; H10W 72/227; H10W 72/232; H10W 72/234; H10W 72/237; H10W 72/248; H10W 72/255; H10W 90/724

(57) ABSTRACT

A chip-size-package type semiconductor device includes a semiconductor layer, pads, and metal redistributions that are located above a top surface of the semiconductor layer and each of which is connected to one or more pads. The metal redistributions include first metal redistributions each of which includes a first portion and a second portion contained within the first portion in a plan view, the second portion being located above the first portion and having an area smaller than an area of the first portion in the plan view. Each of the first metal redistributions includes one or more line-shaped bends in a boundary portion between the first portion and the second portion on a surface of the first metal redistribution, the one or more line-shaped bends each having an interior angle of at least 180 degrees in a cross section of the first metal redistribution.

### CROSS REFERENCE TO RELATED APPLICATIONS

This is a continuation application of PCT International Patent Application No. PCT/JP2024/035507 filed on Oct. 3, 2024, designating the United States of America, which is based on and claims priority of U.S. Provisional Patent Application No. 63/614845 filed on Dec. 26, 2023. The entire disclosures of the above-identified applications, including the specifications, drawings and claims are incorporated herein by reference in their entirety.

### FIELD

The present disclosure relates to semiconductor devices and semiconductor modules.

### BACKGROUND

A conventionally known technique is a technique for mounting a chip-size-package type semiconductor device on a mounting substrate via a solder material.

In addition, a conventionally known technique is a technique for bonding, when a semiconductor device in which a semiconductor chip is molded using, for example, resin or a base material is mounted on a mounting substrate, the terminals of the semiconductor device and the land patterns of the mounting substrate via solder fillets each including a solder bonding material at least a portion of which protrudes to the outside of the semiconductor device in a plan view of the semiconductor device (e.g., see Patent Literature (PTL) 1).

By using this technique, it is possible to determine by visual inspection whether the terminals of a semiconductor device in which a semiconductor chip is molded using, for example, resin or a base material and the land patterns of a mounting substrate are bonded via solder bonding materials when the semiconductor device is mounted on the mounting substrate.

### CITATION LIST

### Patent Literature

PTL 1: Japanese Unexamined Patent Application Publication No. 2020-043236

### SUMMARY

### Technical Problem

On the other hand, conventionally, a technique for bonding, when a chip-size-package type semiconductor device is mounted on a mounting substrate, the terminals of the semiconductor device and the land patterns of the mounting substrate via solder fillets each including a solder bonding material at least a portion of which protrudes to the outside of the semiconductor device in a plan view of the semiconductor device has not been developed.

For this reason, conventionally, it has been impossible to determine by visual inspection whether the terminals of the semiconductor device and the land patterns of the mounting substrate are bonded via the solder bonding materials when the chip-size-package type semiconductor device is mounted on the mounting substrate.

In view of this, the present disclosure provides, for example, a semiconductor device that makes it possible to determine by visual inspection whether the terminals of the semiconductor device and the land patterns of a mounting substrate are bonded via solder bonding materials when the chip-size-package type semiconductor device is mounted on the mounting substrate.

### Solution to Problem

A semiconductor device according to one aspect of the present disclosure is a chip-size-package type semiconductor device, the semiconductor device including: a semiconductor layer; one or more vertical metal-oxide semiconductor (MOS) transistors that are provided in the semiconductor layer; a passivation layer that is located above a top surface of the semiconductor layer and includes a plurality of openings; a plurality of pads each of which is exposed to outside of the passivation layer in a corresponding one of the plurality of openings and functions as a terminal of one of the one or more vertical MOS transistors; and a plurality of metal redistributions that are located above the top surface of the semiconductor layer and each of which is connected to one or more pads that are different from each other among the plurality of pads. In a plan view of the semiconductor device: the passivation layer is contained within the semiconductor layer; and each of the plurality of metal redistributions is contained within the semiconductor layer and contains the one or more pads connected to the metal redistribution. The plurality of metal redistributions include a plurality of first metal redistributions each of which includes a first portion and a second portion contained within the first portion in the plan view, the second portion being located above the first portion and having an area smaller than an area of the first portion in the plan view. Each of the plurality of first metal redistributions includes one or more line-shaped bends in a boundary portion between the first portion and the second portion on a surface of the first metal redistribution, the one or more line-shaped bends each having an interior angle of at least 180 degrees in a cross section of the first metal redistribution. In the plan view, the one or more line-shaped bends include a portion facing a peripheral side of the semiconductor device.

A semiconductor module according to one aspect of the present disclosure includes: the semiconductor device described above; and a mounting substrate on which the semiconductor device is face-down mounted. The mounting substrate includes a plurality of land patterns that correspond to the plurality of metal redistributions included in the semiconductor device on a one-to-one basis. Each of the plurality of land patterns is bonded, via a solder fillet including a solder bonding material, to one metal redistribution corresponding to the land pattern among the plurality of metal redistributions. In the plan view: an area of each of the plurality of land patterns is larger than an area of the one metal redistribution corresponding to the land pattern among the plurality of metal redistributions; and each of the plurality of land patterns includes a portion that is not contained within the semiconductor device. The one or more line-shaped bends included in each of the plurality of first metal redistributions are filled with the solder fillet corresponding to the first metal redistribution.

A semiconductor module according to one aspect of the present disclosure includes: the semiconductor device described above; and a mounting substrate on which the semiconductor device is face-down mounted. The mounting substrate includes a plurality of land patterns that correspond to the plurality of metal redistributions included in the semiconductor device on a one-to-one basis. Each of the plurality of land patterns is bonded, via a solder fillet corresponding to the land pattern and including a solder bonding material, to one metal redistribution corresponding to the land pattern among the plurality of metal redistributions. In the plan view: an area of each of the plurality of land patterns is larger than an area of one metal redistribution corresponding to the land pattern among the plurality of metal redistributions; and each of the plurality of land patterns includes a portion that is not contained within the semiconductor device. The one or more line-shaped bends included in each of the plurality of first metal redistributions are filled with the solder fillet. In the plan view: among the plurality of land patterns, a first land pattern corresponding to a first specific metal redistribution includes: a region that extends beyond a first side to outside of the semiconductor device; and a region that extends beyond a second side to the outside of the semiconductor device; among the plurality of land patterns, a second land pattern corresponding to a second specific metal redistribution includes: a region that extends beyond the second side to the outside of the semiconductor device; and a region that extends beyond a third side to the outside of the semiconductor device; among the plurality of land patterns, a third land pattern corresponding to a third specific metal redistribution includes: a region that extends beyond the third side to the outside of the semiconductor device; and a region that extends beyond a fourth side to the outside of the semiconductor device; and among the plurality of land patterns, a fourth land pattern corresponding to a fourth specific metal redistribution includes: a region that extends beyond the fourth side to the outside of the semiconductor device; and a region that extends beyond the first side to the outside of the semiconductor device.

### Advantageous Effects

A semiconductor device etc. according to one aspect of the present disclosure make it possible to determine by visual inspection whether the terminals of the semiconductor device and the land patterns of a mounting substrate are bonded via solder bonding materials when the chip-size-package type semiconductor device is mounted on the mounting substrate.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a plan view showing an example of a structure of a semiconductor device according to an embodiment.

FIG. 1B is a plan view showing an example of the structure of the semiconductor device according to the embodiment.

FIG. 2 is a cross-sectional schematic diagram showing an example of the structure of the semiconductor device according to the embodiment.

FIG. 3 is a circuit diagram showing the semiconductor device according to the embodiment.

FIG. 4A is a plan view showing an example of a structure of a semiconductor module according to the embodiment.

FIG. 4B is a plan view showing an example of a positional relation between the constituent elements of the semiconductor module according to the embodiment, in a plan view of the semiconductor module.

FIG. 5 is a cross-sectional schematic diagram showing an example of the structure of the semiconductor module according to the embodiment.

FIG. 6A is a cross-sectional schematic diagram showing an example of a structure of the semiconductor device according to the embodiment.

FIG. 6B is a cross-sectional schematic diagram showing an example of a structure of the semiconductor device according to the embodiment.

FIG. 7 is a cross-sectional schematic diagram showing an example of a structure of the semiconductor device according to the embodiment.

FIG. 8A is a plan view showing an example of a structure of the semiconductor device according to the embodiment.

FIG. 8B is a plan view showing an example of a structure of the semiconductor device according to the embodiment.

FIG. 8C is a plan view showing an example of a structure of the semiconductor device according to the embodiment.

FIG. 8D is a plan view showing an example of a structure of the semiconductor device according to the embodiment.

FIG. 8E is a plan view showing an example of a structure of the semiconductor device according to the embodiment.

FIG. 9 is a cross-sectional schematic diagram showing an example of a structure of the semiconductor device according to the embodiment.

FIG. 10 is a cross-sectional schematic diagram showing an example of a structure of the semiconductor module according to the embodiment.

FIG. 11 is a plan view showing an example of a structure of the semiconductor device according to the embodiment.

FIG. 12 is a plan view showing an example of a structure of the semiconductor device according to the embodiment.

FIG. 13 is a plan view showing an example of a structure of the semiconductor device according to the embodiment.

FIG. 14 is a plan view showing an example of a structure of the semiconductor device according to the embodiment.

FIG. 15 is a plan view showing an example of a structure of the semiconductor device according to the embodiment.

### DESCRIPTION OF EMBODIMENT

### Circumstances Leading to One Aspect of the Present Disclosure

As stated above, conventionally, it has been impossible to determine by visual inspection whether the terminals of the semiconductor device and the land patterns of the mounting substrate are bonded via the solder bonding materials when the chip-size-package type semiconductor device is mounted on the mounting substrate.

For this reason, it is necessary to use, for example, an X-ray inspection device to determine whether the terminals of the chip-size-package type semiconductor device and the land patterns of the mounting substrate are bonded via the solder bonding materials.

Accordingly, it is difficult to efficiently determine whether the terminals of the chip-size-package type semiconductor device and the land patterns of the mounting substrate are bonded via the solder bonding materials.

In view of this, if it is possible to determine by visual inspection whether the terminals of the chip-size-package type semiconductor device and the land patterns of the mounting substrate are bonded via the solder bonding materials, it is possible to efficiently determine whether the terminals of the chip-size-package type semiconductor device and the land patterns of the mounting substrate are bonded via the solder bonding materials, by using, for example, a substrate visual inspection device that performs an automated optical inspection (AOI).

In response, the inventors diligently conducted repeated experiments and analyses to achieve a technique capable of determining by visual inspection whether the terminals of a chip-size-package type semiconductor and the land patterns of a mounting substrate are bonded via solder bonding materials.

As a result, the inventors arrived at a semiconductor device etc. according to the present disclosure.

A semiconductor device according to one aspect of the present disclosure is a chip-size-package type semiconductor device, the semiconductor device including: a semiconductor layer; one or more vertical metal-oxide semiconductor (MOS) transistors that are provided in the semiconductor layer; a passivation layer that is located above a top surface of the semiconductor layer and includes a plurality of openings; a plurality of pads each of which is exposed to outside of the passivation layer in a corresponding one of the plurality of openings and functions as a terminal of one of the one or more vertical MOS transistors; and a plurality of metal redistributions that are located above the top surface of the semiconductor layer and each of which is connected to one or more pads that are different from each other among the plurality of pads. In a plan view of the semiconductor device: the passivation layer is contained within the semiconductor layer; and each of the plurality of metal redistributions is contained within the semiconductor layer and contains the one or more pads connected to the metal redistribution. The plurality of metal redistributions include a plurality of first metal redistributions each of which includes a first portion and a second portion contained within the first portion in the plan view, the second portion being located above the first portion and having an area smaller than an area of the first portion in the plan view. Each of the plurality of first metal redistributions includes one or more line-shaped bends in a boundary portion between the first portion and the second portion on a surface of the first metal redistribution, the one or more line-shaped bends each having an interior angle of at least 180 degrees in a cross section of the first metal redistribution. In the plan view, the one or more line-shaped bends include a portion facing a peripheral side of the semiconductor device.

The semiconductor device thus configured makes it possible to provide a plurality of solder fillets that bond the plurality of land patterns and the plurality of metal redistributions on a one-to-one basis when the chip-size-package type semiconductor device thus configured is mounted on the mounting substrate including the plurality of land patterns each corresponding to a different one of the plurality of metal redistributions, the plurality of solder fillets each including a solder bonding material at least a portion of which protrudes to the outside of the semiconductor device in the plan view of the semiconductor device.

For this reason, the semiconductor device thus configured makes it possible to bond the plurality of pads functioning as the terminals of the semiconductor device and the plurality of land patterns of the mounting substrate via the plurality of solder fillets when the chip-size-package type semiconductor device is mounted on the mounting substrate.

Accordingly, the semiconductor device thus configured makes it possible to determine by visual inspection whether the terminals of the semiconductor device and the land patterns of the mounting substrate are bonded via the solder bonding materials when the chip-size-package type semiconductor device is mounted on the mounting substrate.

As described above, the semiconductor device thus configured makes it possible to bond the terminals of the semiconductor device and the land patterns of the mounting substrate via the plurality of solder fillets when the chip-size-package type semiconductor device thus configured is mounted on the mounting substrate.

For this reason, the semiconductor device thus configured makes it possible to reduce an excessive concentration of stress in regions in which the terminals of the semiconductor device and the land patterns of the mounting substrate are bonded, compared to a semiconductor device in which the terminals of the semiconductor device and the land patterns of a mounting substrate are bonded via solder bonding materials that are not in the form of the plurality of solder fillets.

Accordingly, the semiconductor device thus configured makes it possible to improve the reliability of a semiconductor module configured by bonding the semiconductor device and the mounting substrate.

In general, a metal redistribution including a line-shaped bend is bonded to a bonding material more strongly than a metal redistribution including no line-shaped bend is.

In the semiconductor device thus configured, the plurality of metal redistributions include a plurality of first metal redistributions each of which includes one or more line-shaped bends.

For this reason, the semiconductor device thus configured makes it possible to cause the bond between the plurality of metal redistributions and the plurality of solder fillets to be relatively strong.

Accordingly, the semiconductor device thus configured makes it possible to further improve the reliability of the semiconductor module configured by bonding the semiconductor device and the mounting substrate.

Moreover, a length of the second portion in a direction in which a normal line extends from the top surface of the semiconductor layer may be greater than a length of the first portion in the direction.

As a result, it is possible to cause the plurality of solder fillets each of which is bonded to a corresponding one of the plurality of first metal redistributions to be relatively high.

For this reason, it is possible to further reduce the excessive concentration of the stress in the regions in which the terminals of the semiconductor device and the land patterns of the mounting substrate are bonded.

Accordingly, the semiconductor device thus configured makes it possible to further improve the reliability of the semiconductor module configured by bonding the semiconductor device and the mounting substrate.

Furthermore, a region having an angle of elevation of less than 90 degrees relative to the top surface of the semiconductor layer may be located in a region of a lateral surface of the second portion, the region of the lateral surface of the second portion facing the peripheral side of the semiconductor device in the plan view.

As a result, it is possible to increase bonding strength between the plurality of solder fillets and the plurality of first metal redistributions.

Moreover, a periphery of the passivation layer may be located inward of a periphery of the semiconductor layer in the plan view, and a lowermost surface of the first portion: may be closer to the top surface of the semiconductor layer than the plurality of pads are in the direction; may be contained within the semiconductor layer in the plan view; and need not be contained within the periphery of the passivation layer in the plan view.

As a result, it is possible to cause the plurality of solder fillets each of which is bonded to the corresponding one of the plurality of first metal redistributions to be much higher.

For this reason, it is possible to further reduce the excessive concentration of the stress in the regions in which the terminals of the semiconductor device and the land patterns of the mounting substrate are bonded.

Accordingly, the semiconductor device thus configured makes it possible to further improve the reliability of the semiconductor module configured by bonding the semiconductor device and the mounting substrate.

Furthermore, in the plan view: a portion that is not contained within the periphery of the passivation layer may be located on a periphery of the first portion; and the second portion may be contained within the periphery of the passivation layer.

Moreover, each of the plurality of metal redistributions may include a multi-layer structure including: a first metal layer made of a first metal excluding gold; and a second metal layer made of a second metal including gold, a first region flush with a lateral surface of the semiconductor layer may be located in a lateral surface of the first portion in the plan view, and the first metal may be exposed in at least a portion of the first region.

In general, when a solder bonding material is gold-tin solder, the solder bonding material is not bonded to a metal excluding gold.

For this reason, when a solder bonding material is gold-tin solder, the semiconductor device thus configured makes it possible to reduce contact between the solder bonding material and the lateral surface of the semiconductor layer.

Furthermore, each of the plurality of metal redistributions may include a multi-layer structure including: a first metal layer made of a first metal excluding gold; and a second metal layer made of a second metal including gold, a lateral surface of the first portion is located inward of a lateral surface of the semiconductor layer in the plan view, and the first metal is not exposed on an entirety of the lateral surface of the first portion, and the second metal is exposed on the entirety of the lateral surface of the first portion.

In general, when a solder bonding material is gold-tin solder, the solder bonding material is bonded to a metal including gold well.

For this reason, when a solder bonding material is gold-tin solder, the semiconductor device thus configured makes it possible to cause the bond between the plurality of metal redistributions and the plurality of solder fillets to be relatively strong.

Accordingly, the semiconductor device thus configured makes it possible to further improve the reliability of the semiconductor module configured by bonding the semiconductor device and the mounting substrate.

Moreover, in the plan view: the one or more line-shaped bends may further include a portion facing a central side of the semiconductor device; and a shortest distance between a peripheral portion of the first portion and the portion of the one or more line-shaped bends facing the peripheral side of the semiconductor device may be longer than a shortest distance between the peripheral portion of the first portion and the portion of the one or more line-shaped bends facing the central side of the semiconductor device.

As a result, it is possible to cause the bond between the plurality of first metal redistributions and the plurality of solder fillets to be stronger.

Accordingly, the semiconductor device thus configured makes it possible to further improve the reliability of the semiconductor module configured by bonding the semiconductor device and the mounting substrate.

Furthermore, a total number of the plurality of metal redistributions may be equal to a total number of the plurality of pads.

As a result, it is possible to use all of the plurality of pads of the semiconductor device effectively in the semiconductor module configured by bonding the semiconductor device and the mounting substrate.

Accordingly, the semiconductor device thus configured makes it possible to achieve the semiconductor module having superior characteristics, compared to a case in which it is impossible to use all of the plurality of pads of the semiconductor device effectively in the semiconductor module.

Moreover, all of the plurality of metal redistributions may be the plurality of first metal redistributions.

As a result, it is possible to cause the bond between all of the plurality of metal redistributions and the plurality of solder fillets to be relatively strong.

Accordingly, the semiconductor device thus configured makes it possible to further improve the reliability of the semiconductor module configured by bonding the semiconductor device and the mounting substrate.

Furthermore, in the plan view: the semiconductor layer may be rectangular; and the plurality of pads may include: a first pad including no other pad between a first side of the semiconductor layer and a second side of the semiconductor layer that is orthogonal to the first side; a second pad including no other pad between the second side and a third side of the semiconductor layer that is orthogonal to the second side; a third pad including no other pad between the third side and a fourth side of the semiconductor layer that is orthogonal to the third side; and a fourth pad including no other pad between the fourth side and the first side, and among the plurality of metal redistributions, each of a first specific metal redistribution connected to the first pad, a second specific metal redistribution connected to the second pad, a third specific metal redistribution connected to the third pad, and a fourth specific metal redistribution connected to the fourth pad may be a different one of the plurality of first metal redistributions.

As a result, it is possible to cause the bond between solder fillets and the four metal redistributions located at the four corners of the semiconductor device that is rectangular in the plan view of the semiconductor device to be relatively strong.

Accordingly, the semiconductor device thus configured makes it possible to further improve the reliability of the semiconductor module configured by bonding the semiconductor device and the mounting substrate.

Moreover, each of the first specific metal redistribution, the second specific metal redistribution, the third specific metal redistribution, and the fourth specific metal redistribution may be connected to two or more pads among the plurality of pads.

Furthermore, among the plurality of pads, at least one of one or more specific pads excluding the first pad, the second pad, the third pad, and the fourth pad may be connected to none of the plurality of metal redistributions.

As a result, it is possible to cause the bond between solder fillets and the four metal redistributions located at the four corners of the semiconductor device that is rectangular in the plan view of the semiconductor device to be relatively strong without connecting the at least one pad to any of the plurality of metal redistributions.

Accordingly, the semiconductor device thus configured makes it possible to reduce costs for providing the plurality of metal redistributions while maintaining the reliability of the semiconductor module configured by bonding the semiconductor device and the mounting substrate.

Moreover, among the plurality of pads, at least one of one or more specific pads excluding the first pad, the second pad, the third pad, and the fourth pad may be connected to, among the plurality of metal redistributions, at least one of a plurality of second metal redistributions that are different from the plurality of first metal redistributions and each of which does not include the one or more line-shaped bends.

As a result, it is possible to cause at least one of the plurality of metal redistributions connected to the at least one of the one or more specific pads to be at least one of the plurality of second metal redistributions that are smaller than the plurality of first metal redistributions in the plan view of the semiconductor device.

Accordingly, the semiconductor device thus configured makes it possible to reduce an increase in the area in the plan view of the semiconductor device.

A semiconductor module according to one aspect of the present disclosure includes: the semiconductor device described above; and a mounting substrate on which the semiconductor device is face-down mounted. The mounting substrate includes a plurality of land patterns that correspond to the plurality of metal redistributions included in the semiconductor device on a one-to-one basis. Each of the plurality of land patterns is bonded, via a solder fillet including a solder bonding material, to one metal redistribution corresponding to the land pattern among the plurality of metal redistributions. In the plan view: an area of each of the plurality of land patterns is larger than an area of the one metal redistribution corresponding to the land pattern among the plurality of metal redistributions; and each of the plurality of land patterns includes a portion that is not contained within the semiconductor device. The one or more line-shaped bends included in each of the plurality of first metal redistributions are filled with the solder fillet corresponding to the first metal redistribution.

In the semiconductor module thus configured, each of the plurality of metal redistributions and the corresponding one of the plurality of land patterns are bonded via the solder fillet that includes the solder bonding material at least a portion of which protrudes to the outside of the semiconductor device in the plan view of the semiconductor device.

Accordingly, the semiconductor module thus configured makes it possible to determine by visual inspection whether the terminals of the semiconductor device and the land patterns of the mounting substrate are bonded via the solder bonding materials when the chip-size-package type semiconductor device is mounted on the mounting substrate.

As described above, in the semiconductor module thus configured, the terminals of the semiconductor device and the land patterns of the mounting substrate are bonded via the plurality of solder fillets when the chip-size-package type semiconductor device thus configured is mounted on the mounting substrate.

For this reason, the semiconductor module thus configured makes it possible to reduce an excessive concentration of stress in regions in which the terminals of the semiconductor device and the land patterns of the mounting substrate are bonded, compared to a conventional semiconductor module in which the terminals of a semiconductor device and the land patterns of a mounting substrate are bonded via solder bonding materials that are not in the form of the plurality of solder fillets.

Accordingly, the semiconductor module thus configured makes it possible to improve the reliability of the semiconductor module.

In general, a metal redistribution including a line-shaped bend is bonded to a bonding material more strongly than a metal redistribution including no line-shaped bend is.

In the semiconductor module thus configured, a plurality of metal redistributions among the plurality of metal redistributions are the plurality of first metal redistributions each of which includes the one or more line-shaped bends.

For this reason, the semiconductor module thus configured makes it possible to cause the bond between the plurality of metal redistributions and the plurality of solder fillets to be relatively strong.

Accordingly, the semiconductor module thus configured makes it possible to further improve the reliability of the semiconductor module.

A semiconductor module according to one aspect of the present disclosure includes: the semiconductor device described above; and a mounting substrate on which the semiconductor device is face-down mounted. The mounting substrate includes a plurality of land patterns that correspond to the plurality of metal redistributions included in the semiconductor device on a one-to-one basis. Each of the plurality of land patterns is bonded, via a solder fillet corresponding to the land pattern and including a solder bonding material, to one metal redistribution corresponding to the land pattern among the plurality of metal redistributions. In the plan view: an area of each of the plurality of land patterns is larger than an area of one metal redistribution corresponding to the land pattern among the plurality of metal redistributions; and each of the plurality of land patterns includes a portion that is not contained within the semiconductor device. The one or more line-shaped bends included in each of the plurality of first metal redistributions are filled with the solder fillet. In the plan view: among the plurality of land patterns, a first land pattern corresponding to the first specific metal redistribution includes: a region that extends beyond the first side to outside of the semiconductor device; and a region that extends beyond the second side to the outside of the semiconductor device; among the plurality of land patterns, a second land pattern corresponding to the second specific metal redistribution includes: a region that extends beyond the second side to the outside of the semiconductor device; and a region that extends beyond the third side to the outside of the semiconductor device; among the plurality of land patterns, a third land pattern corresponding to the third specific metal redistribution includes: a region that extends beyond the third side to the outside of the semiconductor device; and a region that extends beyond the fourth side to the outside of the semiconductor device; and among the plurality of land patterns, a fourth land pattern corresponding to the fourth specific metal redistribution includes: a region that extends beyond the fourth side to the outside of the semiconductor device; and a region that extends beyond the first side to the outside of the semiconductor device.

In the semiconductor module thus configured, each of the plurality of metal redistributions and the corresponding one of the plurality of land patterns are bonded via the solder fillet that includes the solder bonding material at least a portion of which protrudes to the outside of the semiconductor device in the plan view of the semiconductor device.

Accordingly, the semiconductor module thus configured makes it possible to determine by visual inspection whether the terminals of the semiconductor device and the land patterns of the mounting substrate are bonded via the solder bonding materials when the chip-size-package type semiconductor device is mounted on the mounting substrate.

As described above, in the semiconductor module thus configured, the terminals of the semiconductor device and the land patterns of the mounting substrate are bonded via the plurality of solder fillets when the chip-size-package type semiconductor device thus configured is mounted on the mounting substrate.

For this reason, the semiconductor module thus configured makes it possible to reduce an excessive concentration of stress in regions in which the terminals of the semiconductor device and the land patterns of the mounting substrate are bonded, compared to a semiconductor device in which the terminals of the semiconductor device and the land patterns of a mounting substrate are bonded via solder bonding materials that are not in the form of the plurality of solder fillets.

Accordingly, the semiconductor module thus configured makes it possible to improve the reliability of the semiconductor module.

In general, a metal redistribution including a line-shaped bend is bonded to a bonding material more strongly than a metal redistribution including no line-shaped bend is.

In the semiconductor module thus configured, a plurality of metal redistributions among the plurality of metal redistributions are the plurality of first metal redistributions each of which includes the one or more line-shaped bends.

For this reason, the semiconductor module thus configured makes it possible to cause the bond between the plurality of metal redistributions and the plurality of solder fillets to be relatively strong.

Accordingly, the semiconductor module thus configured makes it possible to further improve the reliability of the semiconductor module.

Additionally, the semiconductor module thus configured makes it possible to cause the bond between the plurality of metal redistributions and the plurality of solder fillets to be relatively strong even when force in one or both of the direction in which the first side and the third side extend and the direction in which the second side and the fourth side extend is applied to the semiconductor device.

Accordingly, the semiconductor module thus configured makes it possible to further improve the reliability of the semiconductor module.

Hereinafter, specific examples of the semiconductor device etc. according to one aspect of the present disclosure are described with reference to the Drawings. An embodiment described below shows a specific example of the present disclosure. Accordingly, the numerical values, shapes, constituent elements, the arrangement and connection of the constituent elements, steps (processes), and the order of steps, etc. shown in the following embodiment are mere examples, and are not intended to limit the present disclosure. In addition, each of figures is a schematic diagram and is not necessarily a precise illustration. In each figure, substantially identical constituent elements are assigned the same reference signs, and overlapping descriptions are omitted or simplified.

### Embodiment

### <Structure of Semiconductor Device>

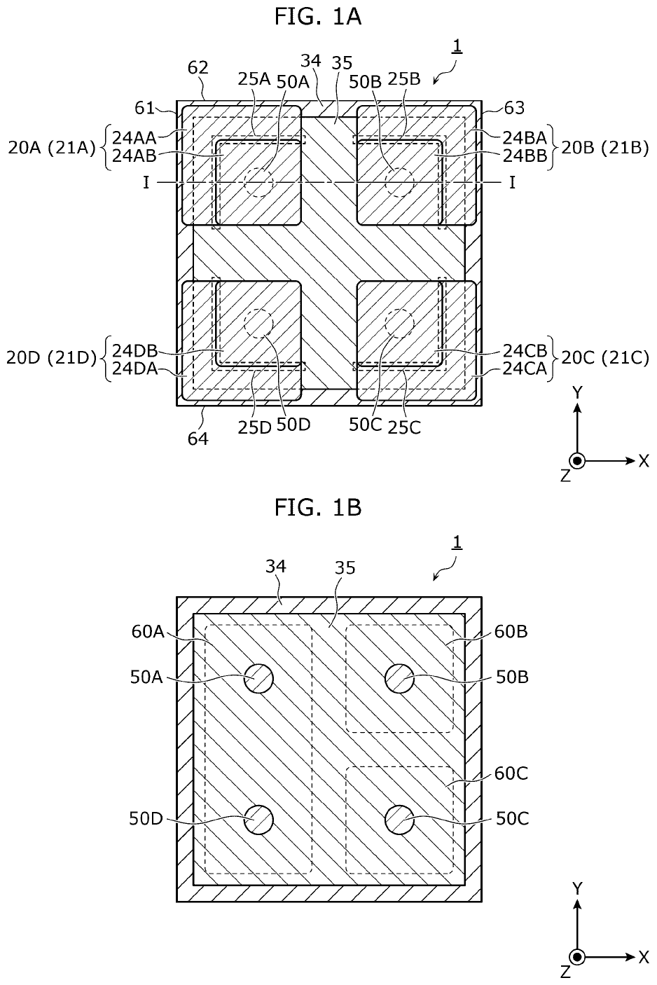

FIG. 1A is a plan view showing an example of a structure of semiconductor device 1 according to the embodiment.

In FIG. 1A, pad 50A (to be described later), pad 50B (to be described later), pad 50C (to be described later), and pad 50D (to be described later) are shown by dashed lines as if pads 50A to 50D could be visually recognized from the outside of semiconductor device 1, but actually pads 50A to 50D cannot be visually recognized directly from the outside of semiconductor device 1.

Additionally, in FIG. 1A, a portion of passivation layer 35 (to be described later) hidden under metal redistribution 20A (to be described later), a portion of passivation layer 35 (to be described later) hidden under metal redistribution 20B (to be described later), a portion of passivation layer 35 (to be described later) hidden under metal redistribution 20C (to be described later), and a portion of passivation layer 35 (to be described later) hidden under metal redistribution 20D (to be described later) are shown by dashed lines as if these portions could be visually recognized from the outside of semiconductor device 1; but actually the portions cannot be visually recognized directly from the outside of semiconductor device 1.

FIG. 1B is a plan view showing an example of the structure of semiconductor device 1 when it is assumed that metal redistribution 20A (to be described later), metal redistribution 20B (to be described later), metal redistribution 20C (to be described later), and metal redistribution 20D (to be described later) are removed from semiconductor device 1. In FIG. 1B, electrode 60A (to be described later), electrode 60B (to be described later), and electrode 60C (to be described later) are shown by dashed lines as if electrodes 60A to 60C could be visually recognized from the outside of semiconductor device 1 when it is assumed that metal redistribution 20A, metal redistribution 20B, metal redistribution 20C, and metal redistribution 20D are removed from semiconductor device 1; but actually electrodes 60A to 60C cannot be visually recognized directly from the outside of semiconductor device 1 when it is assumed that metal redistribution 20A, metal redistribution 20B, metal redistribution 20C, and metal redistribution 20D are removed from semiconductor device 1.

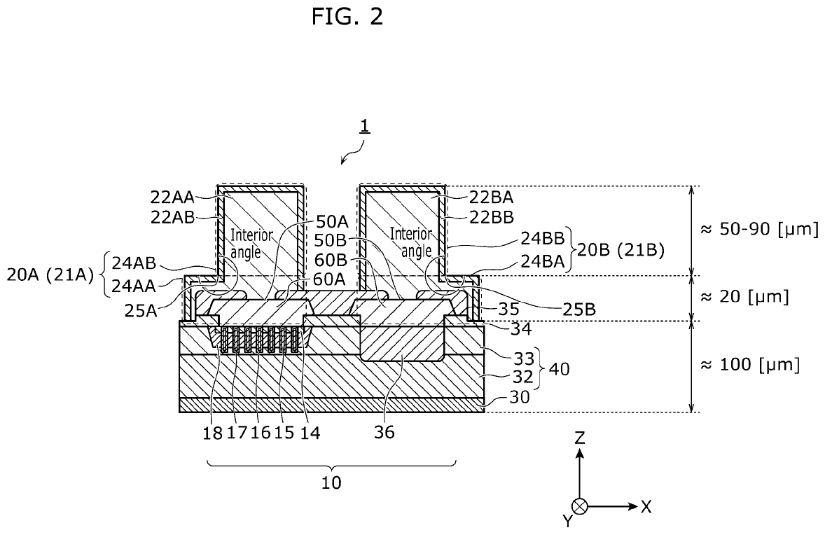

FIG. 2 is a cross-sectional schematic diagram showing an example of the structure of semiconductor device 1, and is a cross-sectional schematic diagram schematically showing a cross section of semiconductor device 1 taken along line I-I in FIG. 1A.

As shown in FIG. 1A, FIG. 1B, and FIG. 2, semiconductor device 1 includes semiconductor layer 40, oxide film 34, passivation layer 35, metal layer 30, a plurality of electrodes 60 (here, corresponding to electrode 60A, electrode 60B, and electrode 60C), a plurality of pads 50 (here, corresponding to pad 50A, pad 50B, pad 50C, and pad 50D), and a plurality of metal redistributions 20 (here, corresponding to metal redistribution 20A, metal redistribution 20B, metal redistribution 20C, and metal redistribution 20D).

Although a configuration in which the plurality of electrodes 60 are electrode 60A, electrode 60B, and electrode 60C is described as an example below, this configuration is one example, and the plurality of electrodes 60 need not be limited to three electrodes.

In the following description, electrode 60A, electrode 60B, and electrode 60C are each also simply referred to as electrode 60, except in a case in which it is necessary to describe electrode 60A, electrode 60B, and electrode 60C clearly and separately.

Moreover, although a configuration in which the plurality of pads 50 are pad 50A, pad 50B, pad 50C, and pad 50D is described as an example below, this configuration is one example, and the plurality of pads 50 need not be limited to four pads.

In the following description, pad 50A, pad 50B, pad 50C, and pad 50D are each also simply referred to as pad 50, except in a case in which it is necessary to describe pad 50A, pad 50B, pad 50C, and pad 50D clearly and separately.

Furthermore, although a configuration in which the plurality of metal redistributions 20 are metal redistribution 20A, metal redistribution 20B, metal redistribution 20C, and metal redistribution 20D is described as an example below, this configuration is one example, and the plurality of metal redistributions 20 need not be limited to four metal redistributions.

In the following description, metal redistribution 20A, metal redistribution 20B, metal redistribution 20C, and metal redistribution 20D are each also simply referred to as metal redistribution 20, except in a case in which it is necessary to describe metal redistribution 20A, metal redistribution 20B, metal redistribution 20C, and metal redistribution 20D clearly and separately.

Semiconductor layer 40 is configured by stacking semiconductor substrate 32 and low-concentration impurity layer 33.

As a non-limiting example, semiconductor layer 40 may be rectangular in a plan view of semiconductor device 1.

In the following description, semiconductor layer 40 is rectangular in the plan view of semiconductor device 1.

Semiconductor substrate 32 is disposed on a back surface side of semiconductor layer 40 and comprises silicon of a first conductivity type that contains impurities having a first concentration.

Low-concentration impurity layer 33 is disposed on a front surface side of semiconductor layer 40, is provided in contact with semiconductor substrate 32, and comprises silicon of the first conductivity type that contains impurities having a second concentration lower than the first concentration. Low-concentration impurity layer 33 may be provided on semiconductor substrate 32 by, for example, epitaxial growth.

In general, semiconductor conductivity types include two kinds of conductivity types that are P-type and N-type. The first conductivity type may be P-type or N-type. For convenience, in the following description, the first conductivity type is N-type and a second conductivity type to be described later is P-type. However, the first conductivity type may be P-type and the second conductivity type may be N-type.

Oxide film 34 is disposed on a top surface of semiconductor layer 40 and provided in contact with low-concentration impurity layer 33.

Passivation layer 35 is located above semiconductor layer 40, is contained within semiconductor layer 40 in the plan view of semiconductor device 1, and includes a plurality of openings. More specifically, passivation layer 35 is a passivation layer that covers top surfaces of oxide film 34, electrode 60A, electrode 60B, and electrode 60C, and includes an opening that exposes pad 50A to the outside of passivation layer 35, an opening that exposes pad 50B to the outside of passivation layer 35, an opening that exposes pad 50C to the outside of passivation layer 35, and an opening that exposes pad 50D to the outside of passivation layer 35.

Although a configuration in which the plurality of openings are the four openings is described as an example below, this configuration is one example, and the plurality of openings need not be limited to four openings.

Here, that passivation layer 35 covers the top surfaces of oxide film 34, electrode 60A, electrode 60B, and electrode 60C refers to a state in which passivation layer 35 has been formed on a substantially entire surface of semiconductor device 1 except the plurality of openings in the plan view of semiconductor device 1. Here, the substantially entire surface of semiconductor device 1 refers to the entire surface of semiconductor device 1 that excludes, of a region of a wafer kept as a dicing margin when semiconductor device 1 is diced from the wafer, a peripheral region slightly remaining in the four sides of semiconductor device 1 after dicing. For this reason, oxide film 34 is exceptionally exposed to the outside of passivation layer 35 in this peripheral region.

In addition, an opening of passivation layer 35 described in the present disclosure refers to a shape obtained by closing the entire periphery of the opening in passivation layer 35 in the plan view of semiconductor device 1. For this reason, a shape obtained by overlapping, in the plan view of semiconductor device 1, a portion of the periphery with the peripheral region in which oxide film 34 is exceptionally exposed to the outside of passivation layer 35 does not correspond to the opening of passivation layer 35 described in the present disclosure.

Metal layer 30 is disposed in contact with an entire back surface of semiconductor layer 40.

Metal layer 30 may include, as a non-limiting example, a multi-layer configuration including a layer comprising silver or copper. It should be noted that metal layer 30 may include a trace amount of a chemical element mixed in as impurities in a manufacturing process.

It should be noted that although the following description is based on the premise that semiconductor device 1 includes metal layer 30, semiconductor device 1 need not be limited to a configuration including metal layer 30.

Metal layer 30 functions as a drain electrode of vertical metal-oxide semiconductor (MOS) transistor 10 to be described later.

In the plan view of semiconductor device 1, body region 18 of the second conductivity type different from the first conductivity type is provided in a region of low-concentration impurity layer 33 contained within electrode 60A, in a range from the top surface of semiconductor layer 40 to a first predetermined depth.

Source region 14 of the first conductivity type containing impurities is provided in body region 18 in a range from the top surface of semiconductor layer 40 to a second predetermined depth at which body region 18 is not penetrated by source region 14.

Additionally, in the plan view of semiconductor device 1, a plurality of gate trenches 17 are provided in a region of low-concentration impurity layer 33 contained within body region 18, in a range from the top surface of semiconductor layer 40 to a third predetermined depth at which source region 14 and body region 18 are penetrated by the plurality of gate trenches 17 to a portion of low-concentration impurity layer 33.

Gate conductor 15 surrounded by gate insulating film 16 is provided inside each of the plurality of gate trenches 17.

Each of gate conductors 15 is electrically connected to electrode 60C.

Gate conductor 15 comprises, as a non-limiting example, polysilicon containing impurities.

In the plan view of semiconductor device 1, drain lead-out region 36 of the first conductivity type that contains impurities having a third concentration higher than the second concentration is provided in a region of low-concentration impurity layer 33 contained within electrode 60B, drain lead-out region 36 penetrating from the top surface of semiconductor layer 40 through low-concentration impurity layer 33 to semiconductor substrate 32.

With the above configuration, semiconductor device 1 includes vertical MOS transistor 10 provided in semiconductor layer 40.

Electrode 60A is an electrode connected to source region 14 and body region 18, and functions as a source electrode of vertical MOS transistor 10.

Electrode 60B is an electrode connected to drain lead-out region 36, and functions as a drain electrode of vertical MOS transistor 10.

In the present embodiment, semiconductor device 1 includes drain electrodes on both the front surface side and the back surface side. In other words, semiconductor device 1 includes: electrode 60B functioning as the drain electrode on the front surface side; and metal layer 30 functioning as the drain electrode on the back surface side.

Electrode 60C is an electrode connected to gate conductor 15, and functions as a gate electrode of vertical MOS transistor 10.

To put it another way, each of the plurality of electrodes 60 functions as an electrode of vertical MOS transistor 10.

Although a configuration in which a vertical MOS transistor included in semiconductor device 1 is one vertical MOS transistor 10 is described as an example below, this configuration is one example, and the number of vertical MOS transistors included in semiconductor device 1 need not be limited to one as long as the number of the vertical MOS transistors included in semiconductor device 1 is at least one.

In addition, although a configuration in which each of the plurality of electrodes 60 functions as an electrode of vertical MOS transistor 10 is described as an example below, this configuration is one example when semiconductor device 1 includes one vertical MOS transistor 10, and each of the plurality of electrodes 60 functions as an electrode of one of one or more vertical MOS transistors 10 when semiconductor device 1 includes one or more vertical MOS transistors 10.

Electrode 60A is exposed to the outside of passivation layer 35 in two openings of passivation layer 35. Portions of the top surface of electrode 60A exposed to the outside of passivation layer 35 in the two openings of passivation layer 35 are pad 50A and pad 50D.

In other words, pad 50A is a portion of the top surface of electrode 60A exposed to the outside of passivation layer 35 in one of the two openings, and pad 50D is a portion of the top surface of electrode 60A exposed to the outside of passivation layer 35 in an other of the two openings.

For this reason, pad 50A functions as a source terminal of vertical MOS transistor 10. Additionally, pad 50D functions as a source terminal of vertical MOS transistor 10.

Electrode 60B is exposed to the outside of passivation layer 35 in an opening of passivation layer 35. The top surface of electrode 60B exposed to the outside of passivation layer 35 in the opening of passivation layer 35 is pad 50B.

In other words, pad 50B is a portion of the top surface of electrode 60B exposed to the outside of passivation layer 35 in the opening.

For this reason, pad 50B functions as a drain terminal of vertical MOS transistor 10.

Electrode 60C is exposed to the outside of passivation layer 35 in an opening of passivation layer 35. The top surface of electrode 60C exposed to the outside of passivation layer 35 in the opening of passivation layer 35 is pad 50C.

In other words, pad 50C is a portion of the top surface of electrode 60C exposed to the outside of passivation layer 35 in the opening.

For this reason, pad 50C functions as a gate terminal of vertical MOS transistor 10.

To put it another way, each of the plurality of pads 50 functions as a terminal of vertical MOS transistor 10.

It should be noted that although a configuration in which each of the plurality of pads 50 functions as a terminal of vertical MOS transistor 10 is described as an example below, this configuration is one example when semiconductor device 1 includes one vertical MOS transistor 10, and each of the plurality of pads 50 functions as a terminal of one of one or more vertical MOS transistors 10 when semiconductor device 1 includes one or more vertical MOS transistors 10.

It should be noted that when semiconductor device 1 further includes an element other than one or more vertical MOS transistors 10, the plurality of pads 50 may include a pad that functions as a terminal of the element.

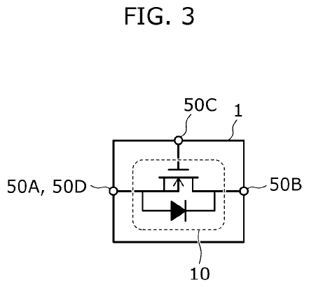

FIG. 3 is a circuit diagram showing semiconductor device 1.

As shown in FIG. 3, semiconductor device 1 includes: vertical MOS transistor 10; pad 50A and pad 50D functioning as the source terminals of vertical MOS transistor 10; pad 50B functioning as the drain terminal of vertical MOS transistor 10; and pad 50C functioning as the gate terminal of vertical MOS transistor 10.

Referring to FIG. 1A, FIG. 1B, and FIG. 2 again, the description of the structure of semiconductor device 1 is continued.

Metal redistribution 20A is located above the top surface of semiconductor layer 40 and connected to pad 50A.

Metal redistribution 20A is contained within semiconductor layer 40 and contains pad 50A in the plan view of semiconductor device 1.

Metal redistribution 20B is located above the top surface of semiconductor layer 40 and connected to pad 50B.

Metal redistribution 20B is contained within semiconductor layer 40 and contains pad 50B in the plan view of semiconductor device 1.

Metal redistribution 20C is located above the top surface of semiconductor layer 40 and connected to pad 50C.

Metal redistribution 20C is contained within semiconductor layer 40 and contains pad 50C in the plan view of semiconductor device 1.

Metal redistribution 20D is located above the top surface of semiconductor layer 40 and connected to pad 50D.

Metal redistribution 20D is contained within semiconductor layer 40 and contains pad 50D in the plan view of semiconductor device 1.

The plurality of metal redistributions 20 include a plurality of first metal redistributions 21 (here, corresponding to first metal redistribution 21A, first metal redistribution 21B, first metal redistribution 21C, and first metal redistribution 21D) each of which includes first portion 24A (here, corresponding to first portion 24AA, first portion 24BA, first portion 24CA, and first portion 24DA) and second portion 24B (here, corresponding to second portion 24AB, second portion 24BB, second portion 24CB, and second portion 24DB) contained within first portion 24A in the plan view of semiconductor device 1, second portion 24B being located above first portion 24A and having an area smaller than an area of first portion 24A in the plan view of semiconductor device 1.

In other words, at least two of the plurality of metal redistributions 20 are first metal redistributions 21.

Although a configuration in which all the plurality of metal redistributions 20 are first metal redistributions 21 is described as an example below, all the plurality of metal redistributions 21 need not be limited to first metal redistributions 21.

In the following description, first portion 24AA, first portion 24BA, first portion 24CA, and first portion 24DA are each also simply referred to as first portion 24A, except in a case in which it is necessary to describe first portion 24AA, first portion 24BA, first portion 24CA, and first portion 24DA clearly and separately.

Moreover, in the following description, second portion 24AB, second portion 24BB, second portion 24CB, and second portion 24DB are each also simply referred to as second portion 24B, except in a case in which it is necessary to describe second portion 24AB, second portion 24BB, second portion 24CB, and second portion 24DB clearly and separately.

Furthermore, in the following description, first metal redistribution 21A, first metal redistribution 21B, first metal redistribution 21C, and first metal redistribution 21D are each also simply referred to as first metal redistribution 21, except in a case in which it is necessary to describe first metal redistribution 21A, first metal redistribution 21B, first metal redistribution 21C, and first metal redistribution 21D clearly and separately.

Each of the plurality of first metal redistributions 21 includes one or more line-shaped bends 25 (here, corresponding to line-shaped bend 25A, line-shaped bend 25B, line-shaped bend 25C, and line-shaped bend 25D) in a boundary portion between first portion 24A and second portion 24B on the surface of first metal redistribution 21, one or more line-shaped bends 25 each having an interior angle of at least 180 degrees in a cross section of first metal redistribution 21.

In the following description, line-shaped bend 25A, line-shaped bend 25B, line-shaped bend 25C, and line-shaped bend 25D are each also simply referred to as line-shaped bend 25, except in a case in which it is necessary to describe line-shaped bend 25A, line-shaped bend 25B, line-shaped bend 25C, and line-shaped bend 25D clearly and separately.

In the plan view of semiconductor device 1, line-shaped bend 25 includes a portion facing a peripheral side of semiconductor device 1. However, not all portions of each of the plurality of first metal redistributions 21 facing the peripheral side of semiconductor device 1 need to include line-shaped bend 25.

The height (the length in the Z direction in FIG. 1A, FIG. 1B, and FIG. 2) of first portion 24A may be, as a non-limiting example, approximately 20 μm, and the height of second portion 24B may be, as a non-limiting example, approximately 50 μm to 90 μm.

As shown in FIG. 2, each of the plurality of metal redistributions 20 may include, as a non-limiting example, a multi-layer structure that includes: first metal layer 22A (corresponding to first metal layer 22AA and first metal layer 22BA in FIG. 2) made of a first metal excluding gold; and second metal layer 22B (corresponding to second metal layer 22AB and second metal layer 22BB in FIG. 2) made of a second metal including gold.

Although the following description is based on the premise that each of the plurality of metal redistributions 20 includes the multi-layer structure including first metal layer 22A and second metal layer 22B, each of the plurality of metal redistributions 20 need not be limited to the multi-layer structure including first metal layer 22A and second metal layer 22B.

In the following description, first metal layer 22AA and first metal layer 22BA are each also simply referred to as first metal layer 22A, except in a case in which it is necessary to describe first metal layer 22AA and first metal layer 22BA clearly and separately.

Additionally, in the following description, second metal layer 22AB and second metal layer 22BB are each also simply referred to as second metal layer 22B, except in a case in which it is necessary to describe second metal layer 22AB and second metal layer 22BB clearly and separately.

First metal layer 22A may comprise, as a non-limiting example, copper, aluminum, or titanium. It should be noted that first metal layer 22A may include a trace amount of a chemical element mixed in as impurities in a manufacturing process.

First metal layer 22A is formed by, for example, plating.

Second metal layer 22B may comprise, as a non-limiting example, gold. It should be noted that second metal layer 22B may include a trace amount of a chemical element mixed in as impurities in a manufacturing process.

Second metal layer 22B is formed by, for example, plating.

As shown in FIG. 2, each of the plurality of metal redistributions 20 may include a multi-layer structure whose outer layer and inner layer are second metal layer 22B and first metal layer 22A, respectively.

In general, when a solder bonding material is gold-tin solder, the solder bonding material is bonded to gold well.

Additionally, in general, plating allows copper, aluminum, and titanium to achieve a relatively high structure.

Accordingly, when a solder bonding material is gold-tin solder, by causing each of the plurality of metal redistributions 20 to include the above configuration, it is possible to cause the bond between metal redistribution 20 and the solder bonding material to be relatively strong, and cause metal redistribution 20 to be relatively high.

Moreover, each of the plurality of metal redistributions 20 may be configured to further include a third metal layer (not shown in the figure) interposed between first metal layer 22A and second metal layer 22B, in addition to first metal layer 22A and second metal layer 22B.

In this case, the third metal layer may be, for example, a metal layer that functions as a barrier metal that prevents diffusion of the metal in second metal layer 22B into first metal layer 22A.

In this case, the third metal layer may comprise, as a non-limiting example, nickel. It should be noted that the third metal layer may include a trace amount of a chemical element mixed in as impurities in a manufacturing process.

The third metal layer is formed by, for example, plating.

### <Structure of Semiconductor Module>

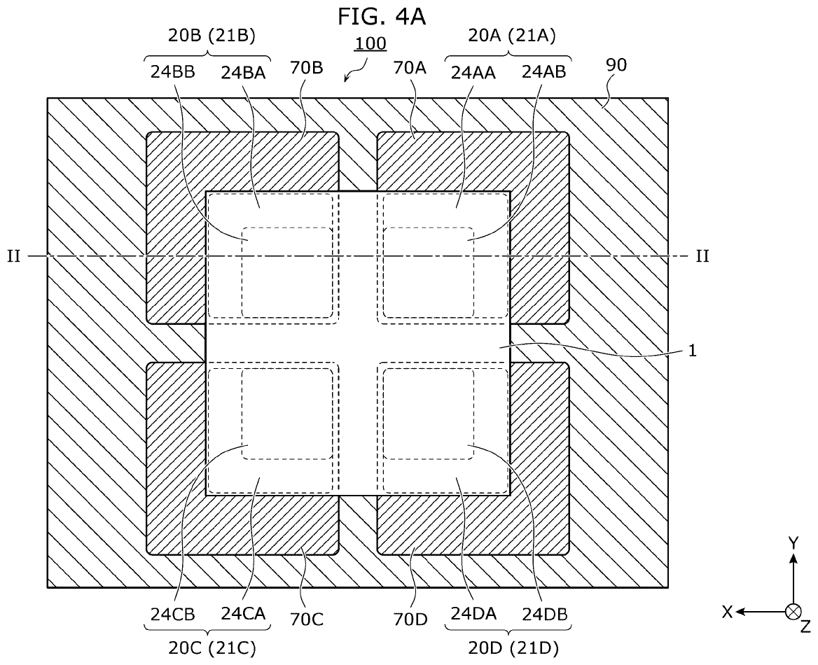

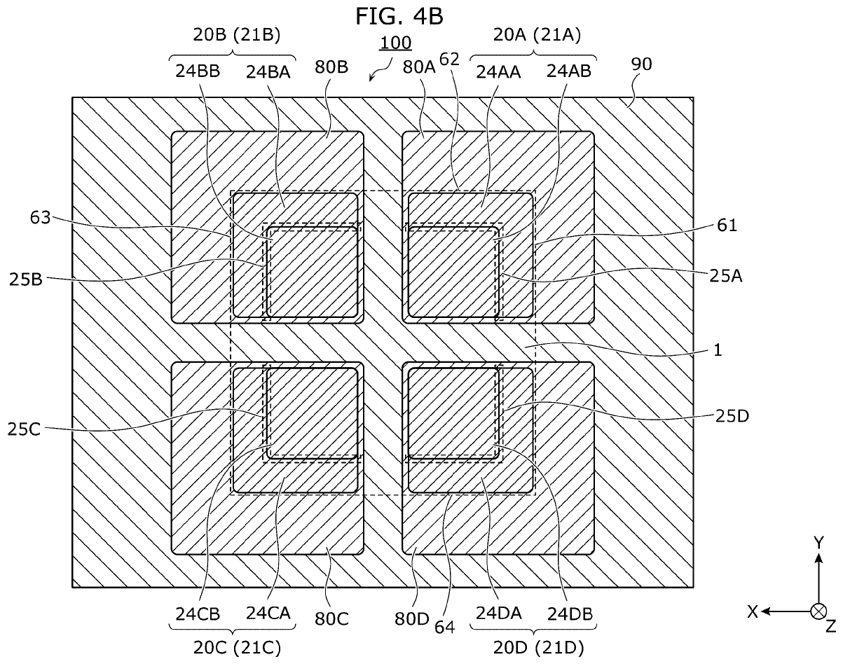

FIG. 4A is a plan view showing an example of a structure of semiconductor module 100 according to the embodiment.

In FIG. 4A, first portion 24AA and second portion 24AB of metal redistribution 20A, first portion 24BA and second portion 24BB of metal redistribution 20B, first portion 24CA and second portion 24CB of metal redistribution 20C, and first portion 24DA and second portion 24DB of metal redistribution 20D are shown by dashed lines as if these portions could be visually recognized in a plan view of semiconductor module 100; but actually the portions cannot be visually recognized directly in the plan view of semiconductor module 100.

Additionally, in FIG. 4A, a portion of solder fillet 70A (to be described later) hidden under semiconductor device 1, a portion of solder fillet 70B (to be described later) hidden under semiconductor device 1, a portion of solder fillet 70C (to be described later) hidden under semiconductor device 1, and a portion of solder fillet 70D (to be described later) hidden under semiconductor device 1 are shown by dashed lines as if these portions could be visually recognized in the plan view of semiconductor module 100; but actually the portions hidden under semiconductor device 1 cannot be visually recognized directly in the plan view of semiconductor module 100.

FIG. 4B is a plan view showing an example of a positional relation between (i) semiconductor device 1 and (ii) first portion 24AA, second portion 24AB, and line-shaped bend 25A of metal redistribution 20A, first portion 24BA, second portion 24BB, and line-shaped bend 25B of metal redistribution 20B, first portion 24CA, second portion 24CB, and line-shaped bend 25C of metal redistribution 20C, first portion 24DA, second portion 24DB, and line-shaped bend 25D of metal redistribution 20D, land pattern 80A (to be described later), land pattern 80B (to be described later), land pattern 80C (to be described later), and land pattern 80D (to be described later), in the plan view of semiconductor module 100.

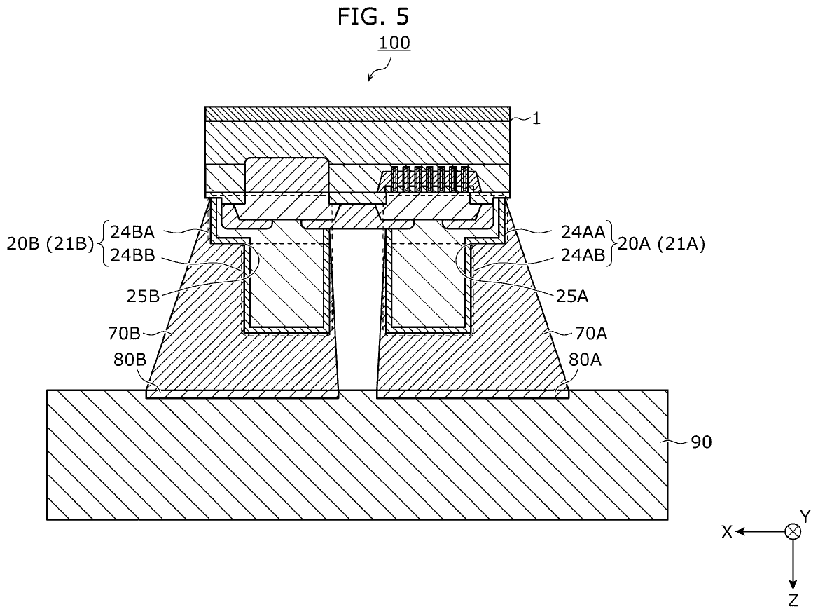

FIG. 5 is a cross-sectional schematic diagram showing an example of the structure of semiconductor module 100, and is a cross-sectional schematic diagram schematically showing a cross section of semiconductor module 100 taken along line II-II in FIG. 4A.

As shown in FIG. 4A, FIG. 4B, and FIG. 5, semiconductor module 100 includes semiconductor device 1, mounting substrate 90, and a plurality of solder fillets 70 (here, corresponding to solder fillet 70A, solder fillet 70B, solder fillet 70C, and solder fillet 70D).

In the following description, solder fillet 70A, solder fillet 70B, solder fillet 70C, and solder fillet 70D are each also simply referred to as solder fillet 70, except in a case in which it is necessary to describe solder fillet 70A, solder fillet 70B, solder fillet 70C, and solder fillet 70D clearly and separately.

Semiconductor device 1 is face-down mounted on mounting substrate 90.

Mounting substrate 90 includes a plurality of land patterns 80 (here, corresponding to land pattern 80A, land pattern 80B, land pattern 80C, and land pattern 80D) that correspond to the plurality of metal redistributions 20 included in semiconductor device 1 on a one-to-one basis.

More specifically, mounting substrate 90 includes land pattern 80A corresponding to metal redistribution 20A, land pattern 80B corresponding to metal redistribution 20B, land pattern 80C corresponding to metal redistribution 20C, and land pattern 80D corresponding to metal redistribution 20D.

In the following description, land pattern 80A, land pattern 80B, land pattern 80C, and land pattern 80D are each also simply referred to as land pattern 80, except in a case in which it is necessary to describe land pattern 80A, land pattern 80B, land pattern 80C, and land pattern 80D clearly and separately.

In the plan view of semiconductor device 1, the area of each of the plurality of land patterns 80 is larger than the area of metal redistribution 20 corresponding to land pattern 80.

In the plan view of semiconductor device 1, each of the plurality of land patterns 80 includes a portion that is not contained within semiconductor device 1.

Each of the plurality of solder fillets 70 includes a solder bonding material, corresponds to a different one of the plurality of land patterns 80 and a different one of the plurality of metal redistributions 20, and bonds corresponding land pattern 80 and corresponding metal redistribution 20.

Here, solder fillet 70A corresponds to land pattern 80A and metal redistribution 20A and bonds land pattern 80A and metal redistribution 20A; solder fillet 70B corresponds to land pattern 80B and metal redistribution 20B and bonds land pattern 80B and metal redistribution 20B; solder fillet 70C corresponds to land pattern 80C and metal redistribution 20C and bonds land pattern 80C and metal redistribution 20C; and solder fillet 70D corresponds to land pattern 80D and metal redistribution 20D and bonds land pattern 80D and metal redistribution 20D.

In other words, land pattern 80A is bonded to metal redistribution 20A via solder fillet 70A; land pattern 80B is bonded to metal redistribution 20B via solder fillet 70B; land pattern 80C is bonded to metal redistribution 20C via solder fillet 70C; and land pattern 80D is bonded to metal redistribution 20D via solder fillet 70D.

One or more line-shaped bends 25 in each of the plurality of first metal redistributions 21 (here, all of the plurality of metal redistributions 20 are first metal redistributions 21) among the plurality of metal redistributions 20 is filled with solder fillet 70 corresponding to first metal redistribution 21.

Here, line-shaped bend 25A of first metal redistribution 21A is filled with solder fillet 70A; line-shaped bend 25B of first metal redistribution 21B is filled with solder fillet 70B; line-shaped bend 25C of first metal redistribution 21C is filled with solder fillet 70C; and line-shaped bend 25D of first metal redistribution 21D is filled with solder fillet 70D.

### <Discussion>

Semiconductor device 1 thus configured makes it possible to provide the plurality of solder fillets 70 that bond the plurality of land patterns 80 and the plurality of metal redistributions 20 on a one-to-one basis when chip-size-package type semiconductor device 1 thus configured is mounted on mounting substrate 90 including the plurality of land patterns 80 each corresponding to a different one of the plurality of metal redistributions 20, the plurality of solder fillets 70 each including a solder bonding material at least a portion of which protrudes to the outside of semiconductor device 1 in the plan view of semiconductor device 1.

For this reason, semiconductor device 1 thus configured makes it possible to bond the plurality of pads 50 functioning as the terminals of semiconductor device 1 and the plurality of land patterns 80 of mounting substrate 90 via the plurality of solder fillets 70 when chip-size-package type semiconductor device 1 thus configured is mounted on mounting substrate 90.

Accordingly, semiconductor device 1 thus configured makes it possible to determine by visual inspection whether the terminals of semiconductor device 1 and the plurality of land patterns 80 of mounting substrate 90 are bonded via the solder bonding materials when chip-size-package type semiconductor device 1 is mounted on mounting substrate 90.

In addition, as described above, semiconductor device 1 thus configured makes it possible to bond the terminals of semiconductor device 1 and the plurality of land patterns 80 of mounting substrate 90 via the plurality of solder fillets 70 when chip-size-package type semiconductor device 1 thus configured is mounted on mounting substrate 90.

For this reason, semiconductor device 1 thus configured makes it possible to reduce an excessive concentration of stress in regions in which the terminals of semiconductor device 1 and the plurality of land patterns 80 of mounting substrate 90 are bonded, compared to a semiconductor device in which the terminals of the semiconductor device and the plurality of land patterns of a mounting substrate are bonded via solder bonding materials that are not in the form of the plurality of solder fillets.

Accordingly, semiconductor device 1 thus configured makes it possible to improve the reliability of semiconductor module 100 configured by bonding semiconductor device 1 and mounting substrate 90.

In general, metal redistribution 20 including line-shaped bend 25 is bonded to a bonding material more strongly than metal redistribution 20 including no line-shaped bend 25 is.

In semiconductor device 1 thus configured, a plurality of metal redistributions among the plurality of metal redistributions 20 are the plurality of first metal redistributions 21 each of which includes one or more line-shaped bends 25.

For this reason, semiconductor device 1 thus configured makes it possible to cause the bond between the plurality of metal redistributions 20 and the plurality of solder fillets 70 to be relatively strong.

Accordingly, semiconductor device 1 thus configured makes it possible to further improve the reliability of semiconductor module 100 configured by bonding semiconductor device 1 and mounting substrate 90.

As shown in FIG. 2, a length of second portion 24B in a direction in which a normal line extends from the top surface of semiconductor layer 40 (the Z direction in FIG. 1A, FIG. 1B, and FIG. 2) may be greater than a length of first portion 24A in the direction in which the normal line extends.

As a result, it is possible to cause the plurality of solder fillets 70 each of which is bonded to a corresponding one of the plurality of first metal redistributions 21 to be relatively high.

For this reason, it is possible to further reduce the excessive concentration of the stress in the regions in which the terminals of semiconductor device 1 and the plurality of land patterns 80 of mounting substrate 90 are bonded.

Accordingly, semiconductor device 1 thus configured makes it possible to further improve the reliability of semiconductor module 100 configured by bonding semiconductor device 1 and mounting substrate 90.

A shape of second portion 24B need not be limited to the shape exemplified in FIG. 1A, FIG. 1B, and FIG. 2.

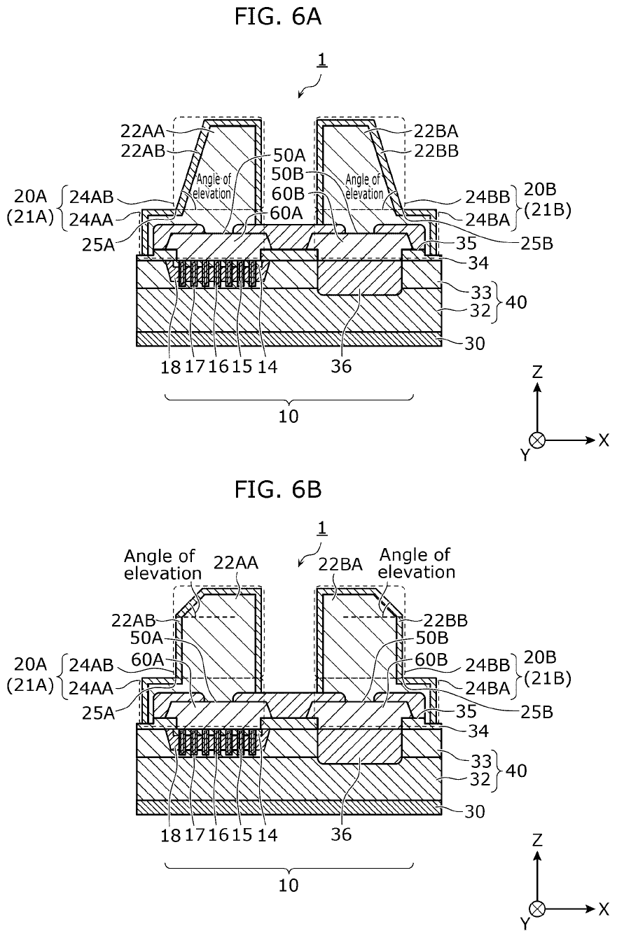

FIG. 6A and FIG. 6B are each a cross-sectional schematic diagram showing an example of a structure of semiconductor device 1 when second portion 24B is in a different shape.

As exemplified in FIG. 6A and FIG. 6B, second portion 24B may be in a shape in which a region having an angle of elevation of less than 90 degrees relative to the top surface of semiconductor layer 40 is located in a region of a lateral surface of second portion 24B facing the peripheral side of semiconductor device 1 in the plan view of semiconductor device 1.

As a result, it is possible to increase bonding strength between the plurality of solder fillets 70 and the plurality of first metal redistributions 21.

It should be noted that as shown in FIG. 1A, FIG. 1B, and FIG. 2, the periphery of passivation layer 35 may be located inward of the periphery of semiconductor layer 40 in the plan view of semiconductor device 1, and the lowermost surface of first portion 24A may be closer to the top surface of semiconductor layer 40 than pads 50 are in a direction (the Z direction in FIG. 1A, FIG. 1B, and FIG. 2) in which a normal line extends from the top surface of semiconductor layer 40, may be contained within semiconductor layer in the plan view of semiconductor device 1, and need not be contained within the periphery of passivation layer 35.

As a result, it is possible to cause the plurality of solder fillets 70 each of which is bonded to the corresponding one of the plurality of first metal redistributions 21 to be much higher.

At this time, as shown in FIG. 1A, FIG. 1B, and FIG. 2, in the plan view of semiconductor device 1, a portion that is not contained within the periphery of passivation layer 35 may be located in the periphery of first portion 24A, and second portion 24B may be contained within the periphery of passivation layer 35.

A shape of first portion 24A need not be limited to the shape exemplified in FIG. 1A, FIG. 1B, and FIG. 2.

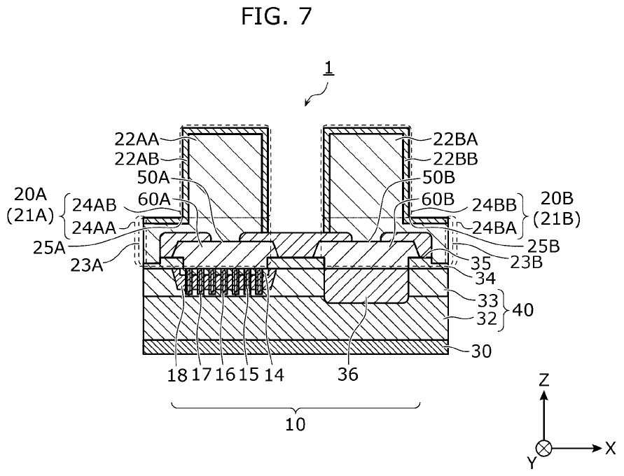

FIG. 7 is a cross-sectional schematic diagram showing a different example of a structure of semiconductor device 1 when first portion 24A is in a different shape.

As exemplified in FIG. 7, first portion 24A may be in a shape in which first region 23 (here, corresponding to first region 23A and first region 23B) flush with a lateral surface of semiconductor layer 40 is located in a lateral surface of first portion 24A in the plan view of semiconductor device 1, and the first metal is exposed in at least a portion of first region 23.

In general, when a solder bonding material is gold-tin solder, the solder bonding material is not bonded to a metal excluding gold.

For this reason, when a solder bonding material is gold-tin solder, semiconductor device 1 thus configured makes it possible to reduce contact between the solder bonding material and the lateral surface of semiconductor layer 40.

It should be noted that the shape of first portion 24A exemplified in FIG. 7 is formed by, for example, cutting first portion 24A, oxide film 34, semiconductor layer 40, and metal layer 30 simultaneously using a dicing blade etc. when semiconductor device 1 is diced from a wafer.

On the other hand, as shown in FIG. 1A, FIG. 1B, and FIG. 2, first portion 24A may be in a shape in which a lateral surface of first portion 24A is located inward of the lateral surface of semiconductor layer 40 in the plan view of semiconductor device 1, and the first metal is not exposed in the entirety of first portion 24A.

As stated above, in general, when a solder bonding material is gold-tin solder, the solder bonding material is bonded to a metal including gold well.

For this reason, when a solder bonding material is gold-tin solder, semiconductor device 1 thus configured makes it possible to cause the bond between the plurality of metal redistributions 20 and the plurality of solder fillets 70 to be relatively strong.

Accordingly, semiconductor device 1 thus configured makes it possible to further improve the reliability of semiconductor module 100 configured by bonding semiconductor device 1 and mounting substrate 90.

A positional relation between first portion 24A and second portion 24B need not be limited to the positional relation exemplified in FIG. 1A, FIG. 1B, and FIG. 2.

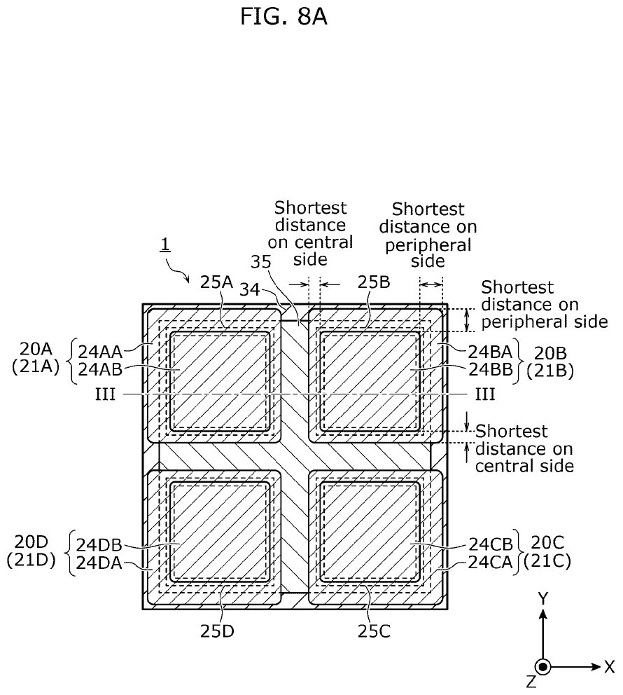

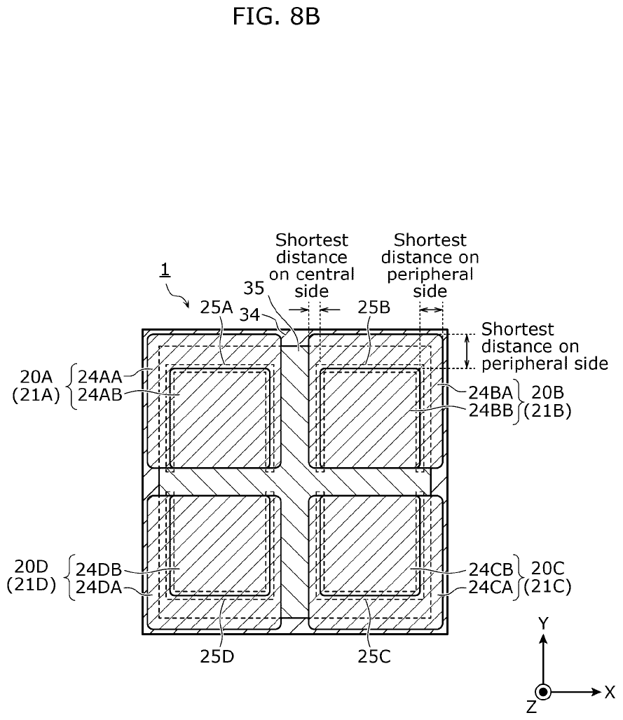

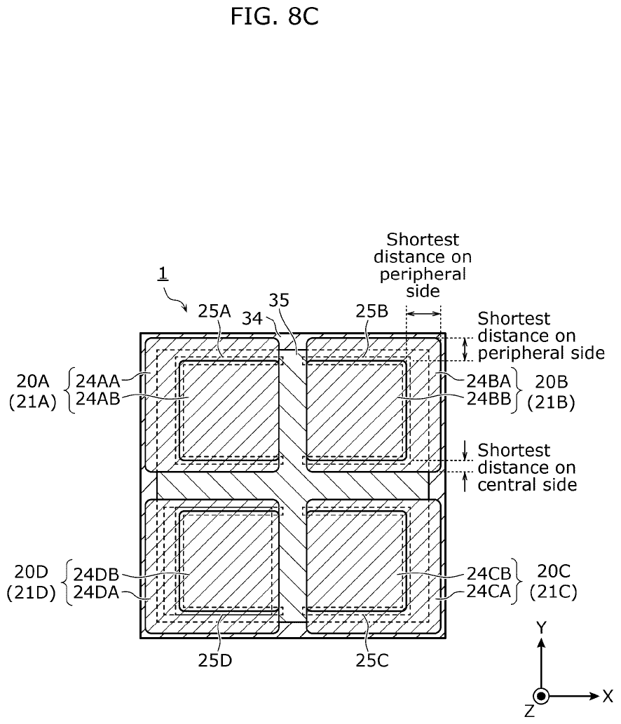

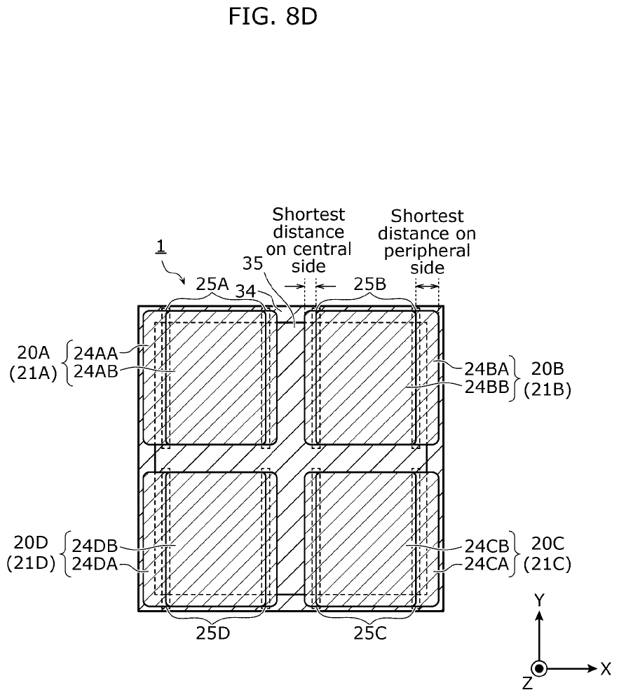

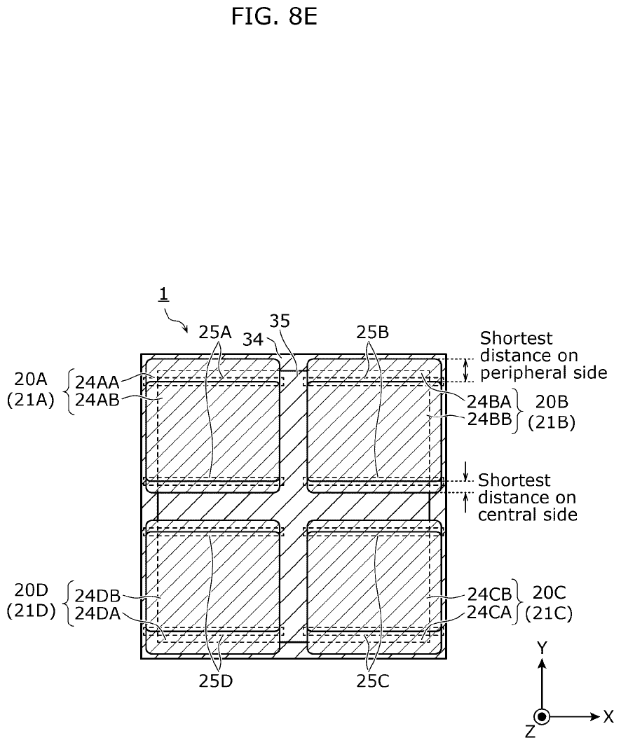

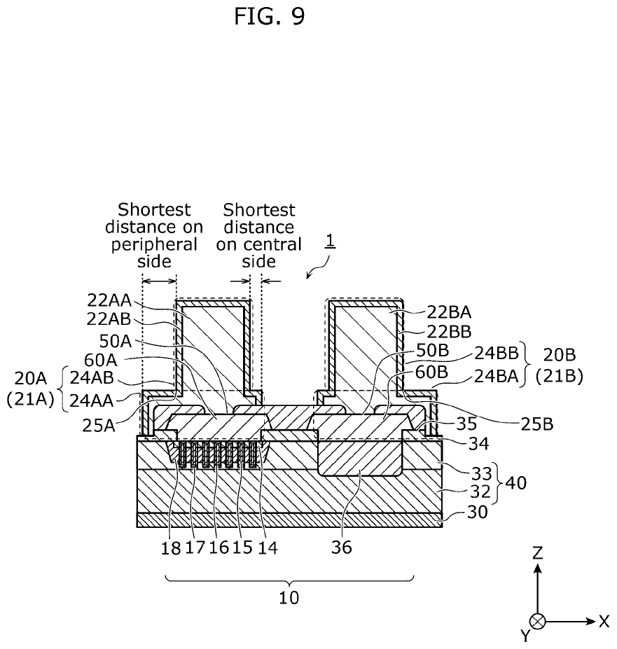

FIG. 8A to FIG. 8E are each a plan view showing an example of a structure of semiconductor device 1 when first portion 24A and second portion 24B are in a different positional relation. FIG. 9 is a cross-sectional schematic diagram showing an example of the structure of semiconductor device 1 when first portion 24A and second portion 24B are in the different positional relation, and is a cross-sectional schematic diagram showing a cross section of semiconductor device 1 taken along line III-III in FIG. 8A.

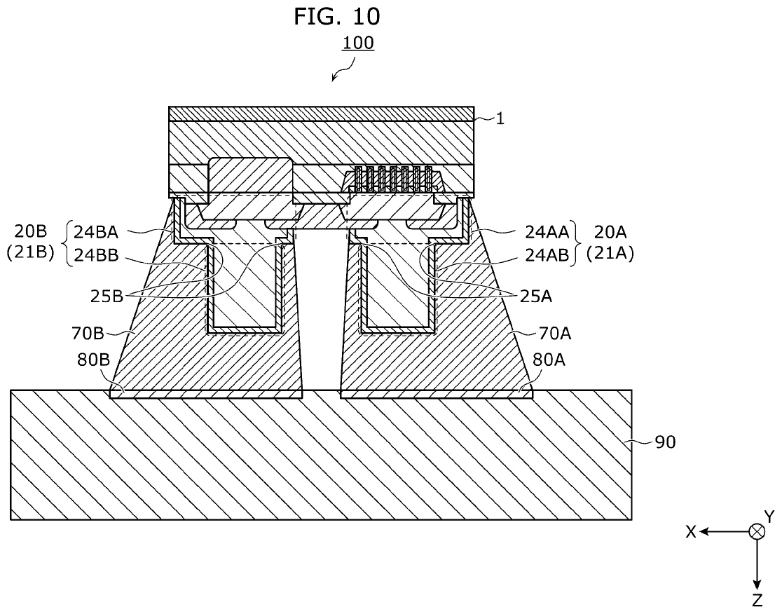

FIG. 10 is a cross-sectional schematic diagram showing an example of a structure of semiconductor module 100 when semiconductor device 1 includes the structure shown in FIG. 8A and FIG. 9.

In FIG. 8A to FIG. 8E, a portion of passivation layer 35 hidden under each first metal redistribution 21 is shown by a dashed line as if the portion could be visually recognized from the outside of semiconductor device 1, but actually the portion cannot be visually recognized directly from the outside of semiconductor device 1.

As exemplified in FIG. 8A to FIG. 8E and FIG. 9, in the plan view of semiconductor device 1, one or more line-shaped bends 25 in each first metal redistribution 21 may further include a portion facing a central side of semiconductor device 1, and the shortest distance between a peripheral portion of first portion 24A and a portion of one or more line-shaped bends 25 facing a peripheral side of semiconductor device 1 may be longer than the shortest distance between the peripheral portion of first portion 24A and the portion of one or more line-shaped bends 25 facing the central side of semiconductor device 1.

Consequently, as shown in FIG. 10, in each first metal redistribution 21, the portion of line-shaped bend 25 facing the central side of semiconductor device 1 is filled with solder fillet 70 in addition to the portion of line-shaped bend 25 facing the peripheral side of semiconductor device 1.

This makes it possible to cause the bond between the plurality of first metal redistributions 21 and the plurality of solder fillets 70 to be stronger.

Accordingly, semiconductor device 1 thus configured makes it possible to further improve the reliability of semiconductor module 100 configured by bonding semiconductor device 1 and mounting substrate 90.

It should be noted that as exemplified in FIG. 8A to FIG. 8C, when one or more line-shaped bends 25 include a portion facing the peripheral side of semiconductor device 1 for each of two different peripheral sides (edges) of semiconductor device 1, the shortest distance between one of the portions and the peripheral portion of first portion 24A may be equal to the shortest distance between an other of the portions and the peripheral portion of first portion 24A.

It should be noted that as shown in FIG. 1A, FIG. 1B, and FIG. 2, the number of the plurality of metal redistributions 20 may be equal to the number of the plurality of pads 50.

As a result, it is possible to use all of the plurality of pads 50 of semiconductor device 1 effectively in semiconductor module 100 configured by bonding semiconductor device 1 and mounting substrate 90.

Accordingly, semiconductor device 1 thus configured makes it possible to achieve semiconductor module 100 having superior characteristics, compared to a case in which it is impossible to use all of the plurality of pads 50 of semiconductor device 1 effectively in semiconductor module 100.

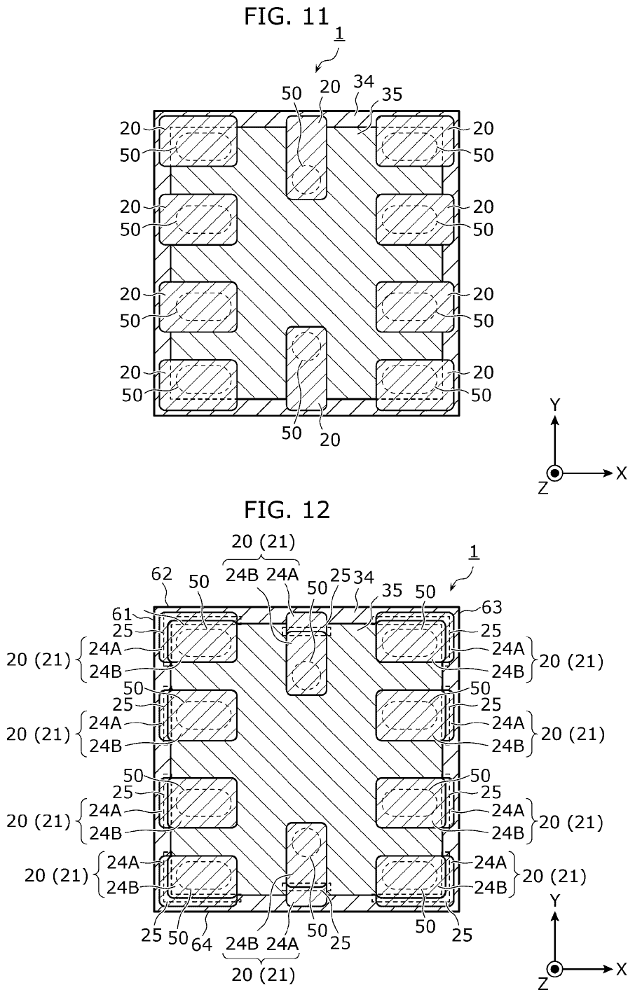

FIG. 11 is a plan view showing a different example of a structure of semiconductor device 1 when the number of a plurality of metal redistributions 20 is equal to the number of a plurality of pads 50.

FIG. 11 is a plan view of semiconductor device 1 when the number of the plurality of metal redistributions 20 included in semiconductor device 1 is 10, and the number of the plurality of pads 50 included in semiconductor device 1 is also 10.

In FIG. 11, the plurality of pads 50 are shown by dashed lines as if these pads could be visually recognized from the outside of semiconductor device 1, but actually the pads cannot be visually recognized directly from the outside of semiconductor device 1.

Additionally, in FIG. 11, a portion of passivation layer 35 hidden under each metal redistribution 20 is shown by a dashed line as if the portion could be visually recognized from the outside of semiconductor device 1, but actually the portion cannot be visually recognized directly from the outside of semiconductor device 1.

It should be noted that as shown in FIG. 1A, FIG. 1B, and FIG. 2, all of the plurality of metal redistributions 20 may be the plurality of first metal redistributions 21.

As a result, it is possible to cause the bond between all of the plurality of metal redistributions 20 and the plurality of solder fillets 70 to be relatively strong.

Accordingly, semiconductor device 1 thus configured makes it possible to further improve the reliability of semiconductor module 100 configured by bonding semiconductor device 1 and mounting substrate 90.

FIG. 12 is a plan view showing an example of a structure of semiconductor device 1 when the number of a plurality of metal redistributions 20 included in semiconductor device 1 is 10, all of the plurality of metal redistributions 20 are a plurality of first metal redistributions 21, and the number of a plurality of pads 50 included in semiconductor device 1 is also 10.

In FIG. 12, the plurality of pads 50 are shown by dashed lines as if these pads could be visually recognized from the outside of semiconductor device 1, but actually the pads cannot be visually recognized directly from the outside of semiconductor device 1.

It should be noted that as shown in FIG. 1A, FIG. 1B, and FIG. 2, in the plan view of semiconductor device 1, semiconductor layer 40 may be rectangular, the plurality of pads 50 may include: pad 50A (hereinafter also referred to as first pad 50A) including no other pad between first side 61 of semiconductor layer 40 and second side 62 of semiconductor layer 40 orthogonal to first side 61; pad 50B (hereinafter also referred to as second pad 50B) including no other pad between second side 62 and third side 63 of semiconductor layer 40 orthogonal to second side 62; pad 50C (hereinafter also referred to as third pad 50C) including no other pad between third side 63 and fourth side 64 of semiconductor layer 40 orthogonal to third side 63; and pad 50D (hereinafter also referred to as fourth pad 50D) including no other pad between fourth side 64 and first side 61, and among the plurality of metal redistributions 20, each of metal redistribution 20A (hereinafter also referred to as first specific metal redistribution 20A) connected to first pad 50A, metal redistribution 20B (hereinafter also referred to as second specific metal redistribution 20B) connected to second pad 50B, metal redistribution 20C (hereinafter also referred to as third specific metal redistribution 20C) connected to third pad 50C, and metal redistribution 20D (hereinafter also referred to as fourth specific metal redistribution 20D) connected to fourth pad 50D may be a different one of the plurality of first metal redistributions 21.

As a result, it is possible to cause the bond between solder fillets 70 and four metal redistributions 20 located at the four corners of semiconductor device 1 that is rectangular in the plan view of semiconductor device 1 to be relatively strong.

Accordingly, semiconductor device 1 thus configured makes it possible to further improve the reliability of semiconductor module 100 configured by bonding semiconductor device 1 and mounting substrate 90.

Semiconductor device 1 exemplified in FIG. 12 is a different example of semiconductor device 1 thus configured.

Moreover, at this time, each of first specific metal redistribution 20A, second specific metal redistribution 20B, third specific metal redistribution 20C, and fourth specific metal redistribution 20D may be connected to two or more pads 50 among the plurality of pads 50.

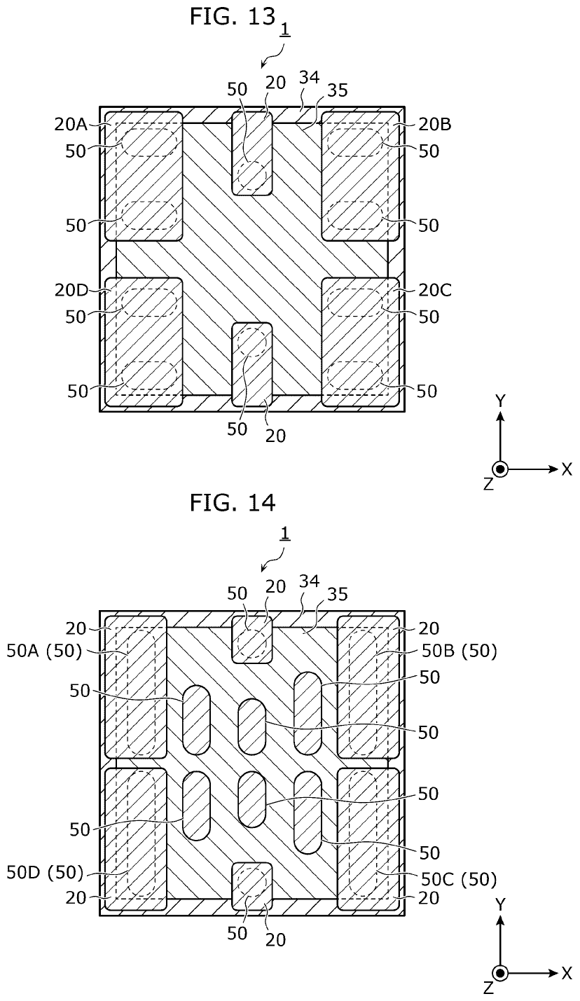

FIG. 13 is a plan view showing an example of a structure of semiconductor device 1 when each of first specific metal redistribution 20A, second specific metal redistribution 20B, third specific metal redistribution 20C, and fourth specific metal redistribution 20D is connected to two or more pads 50 among a plurality of pads 50.

In FIG. 13, the plurality of pads 50 are shown by dashed lines as if these pads could be visually recognized from the outside of semiconductor device 1, but actually the pads cannot be visually recognized directly from the outside of semiconductor device 1.

Additionally, in FIG. 13, a portion of passivation layer 35 hidden under each metal redistribution 20 (including first specific metal redistribution 20A, second specific metal redistribution 20B, third specific metal redistribution 20C, and fourth specific metal redistribution 20D) is shown by a dashed line as if the portion could be visually recognized from the outside of semiconductor device 1, but actually the portion cannot be visually recognized directly from the outside of semiconductor device 1.

Semiconductor device 1 exemplified in FIG. 13 includes, as an example, a configuration in which each of first specific metal redistribution 20A, second specific metal redistribution 20B, third specific metal redistribution 20C, and fourth specific metal redistribution 20D is connected to two pads 50.

FIG. 14 is a plan view showing an example of a structure of semiconductor device 1 when, among a plurality of pads 50, at least one of one or more specific pads excluding first pad 50A, second pad 50B, third pad 50C, and fourth pad 50D is connected to none of a plurality of metal redistributions 20.

In FIG. 14, first pad 50A, second pad 50B, third pad 50C, fourth pad 50D, and two circular pads 50 among the plurality of pads 50 are shown by dashed lines as if these pads could be visually recognized from the outside of semiconductor device 1, but actually the pads cannot be visually recognized directly from the outside of semiconductor device 1.

Additionally, in FIG. 14, a portion of passivation layer 35 hidden under each metal redistribution 20 is shown by a dashed line as if the portion could be visually recognized from the outside of semiconductor device 1, but actually the portion cannot be visually recognized directly from the outside of semiconductor device 1.

As exemplified in FIG. 14, the at least one of the one or more specific pads may be connected to none of the plurality of metal redistributions 20.

As a result, it is possible to cause the bond between solder fillets 70 and four metal redistributions 20 located at the four corners of semiconductor device 1 that is rectangular in the plan view of semiconductor device 1 to be relatively strong without connecting at least one pad 50 to any of the plurality of metal redistributions 20.

Accordingly, semiconductor device 1 thus configured makes it possible to reduce costs for providing the plurality of metal redistributions 20 while maintaining the reliability of semiconductor module 100 configured by bonding semiconductor device 1 and mounting substrate 90.

Semiconductor device 1 exemplified in FIG. 14 includes, as an example, a configuration in which six specific pads (in FIG. 14, six obround pads 50 contained within none of the plurality of metal redistributions 20 in the plan view of semiconductor device 1) out of eight specific pads are connected to none of the plurality of metal redistributions 20. Here, since these six specific pads are connected to none of the plurality of metal redistributions 20, the six specific pads are also connected to none of land patterns 80 of mounting substrate 90.

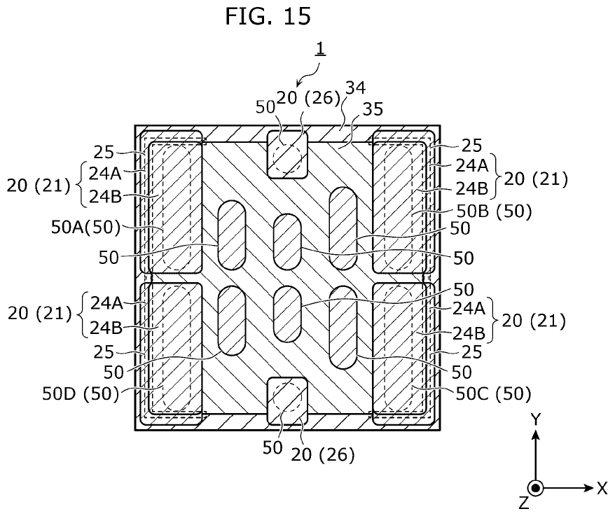

FIG. 15 is a plan view showing a different example of a structure of semiconductor device 1.

In FIG. 15, first pad 50A, second pad 50B, third pad 50C, fourth pad 50D, and two circular pads 50 among a plurality of pads 50 are shown by dashed lines as if these pads could be visually recognized from the outside of semiconductor device 1, but actually the pads cannot be visually recognized directly from the outside of semiconductor device 1.

As shown in FIG. 15, in semiconductor device 1, among the plurality of pads 50, at least one (two circular pads 50 in FIG. 15) of one or more specific pads 50 excluding first pad 50A, second pad 50B, third pad 50C, and fourth pad 50D may be connected to, among a plurality of metal redistributions 20, at least one of a plurality of second metal redistributions 26 that are different from a plurality of first metal redistributions 21 and each of which includes no line-shaped bend 25.

As a result, it is possible to cause at least one of the plurality of metal redistributions 20 connected to the at least one of the one or more specific pads to be the at least one of the plurality of second metal redistributions 26 that are smaller than the plurality of first metal redistributions 21.

Accordingly, semiconductor device 1 thus configured makes it possible to reduce an increase in the area in the plan view of semiconductor device 1.

In semiconductor module 100 including the configuration disclosed in the present embodiment, each of the plurality of metal redistributions 20 and a corresponding one of the plurality of land patterns 80 are bonded via solder fillet 70 at least a portion of which protrudes to the outside of semiconductor device 1 in the plan view of semiconductor device 1.

Accordingly, semiconductor module 100 thus configured makes it possible to determine by visual inspection whether the terminals of semiconductor device 1 and the plurality of land patterns 80 of mounting substrate 90 are bonded via the solder bonding materials when chip-size-package type semiconductor device 1 is mounted on mounting substrate 90.

In addition, as described above, in semiconductor module 100 thus configured, the terminals of semiconductor device 1 and the plurality of land patterns 80 of mounting substrate 90 are bonded via the plurality of solder fillets 70 when chip-size-package type semiconductor device 1 thus configured is mounted on mounting substrate 90.

For this reason, semiconductor module 100 thus configured makes it possible to reduce an excessive concentration of stress in regions in which the terminals of semiconductor device 1 and the plurality of land patterns 80 of mounting substrate 90 are bonded, compared to a conventional semiconductor module in which the terminals of a semiconductor device and the land patterns of a mounting substrate are bonded via solder bonding materials that are not in the form of the plurality of solder fillets.

Accordingly, semiconductor module 100 thus configured makes it possible to improve the reliability of semiconductor module 100.

In general, metal redistribution 20 including line-shaped bend 25 is bonded to a bonding material more strongly than metal redistribution 20 including no line-shaped bend 25 is.

In semiconductor module 100 thus configured, a plurality of metal redistributions among the plurality of metal redistributions 20 are the plurality of first metal redistributions 21 each of which includes one or more line-shaped bends 25.

For this reason, semiconductor module 100 thus configured makes it possible to cause the bond between the plurality of metal redistributions 20 and the plurality of solder fillets 70 to be relatively strong.

Accordingly, semiconductor module 100 thus configured makes it possible to improve the reliability of semiconductor module 100.

It should be noted that as shown in FIG. 4B, when, in the plan view of semiconductor device 1, semiconductor layer 40 is in a rectangular shape that includes first side 61, second side 62 orthogonal to first side 61, third side 63 orthogonal to second side 62, and fourth side 64 orthogonal to third side 63, in the plan view of semiconductor device 1, among the plurality of land patterns 80, land pattern 80A corresponding to first specific metal redistribution 20A may include: a region that extends beyond first side 61 to the outside of semiconductor device 1; and a region that extends beyond second side 62 to the outside of semiconductor device 1, among the plurality of land patterns 80, land pattern 80B corresponding to second specific metal redistribution 20B may include: a region that extends beyond second side 62 to the outside of semiconductor device 1; and a region that extends beyond third side 63 to the outside of semiconductor device 1, among the plurality of land patterns 80, land pattern 80C corresponding to third specific metal redistribution 20C may include: a region that extends beyond third side 63 to the outside of semiconductor device 1; and a region that extends beyond fourth side 64 to the outside of semiconductor device 1, and among the plurality of land patterns 80, land pattern 80D corresponding to fourth specific metal redistribution 20D may include: a region that extends beyond fourth side 64 to the outside of semiconductor device 1; and a region that extends beyond first side 61 to the outside of semiconductor device 1.

As a result, even when force in one or both of the direction (the Y-axis direction in FIG. 4B) in which first side 61 and third side 63 extend and the direction (the X-axis direction in FIG. 4B) in which second side 62 and fourth side 64 extend is applied to semiconductor device 1, it is possible to cause the bond between the plurality of metal redistributions 20 and the plurality of solder fillets 70 to be relatively strong.

Accordingly, semiconductor module 100 thus configured makes it possible to further improve the reliability of semiconductor module 100.

### Supplement

Although the semiconductor device etc. according to one aspect of the present disclosure have been described based on the embodiment, the present disclosure is not limited to the embodiment. Forms obtained by making various modifications to the embodiment that can be conceived by a person skilled in the art may be included in the scope of one or more aspects of the present disclosure, as long as such modifications do not depart from the essence of the present disclosure.

### INDUSTRIAL APPLICABILITY

The present disclosure is widely applicable to chip-size-package semiconductor devices etc.

1. A semiconductor device that is a chip-size-package type semiconductor device, the semiconductor device comprising:
a semiconductor layer;
one or more vertical metal-oxide semiconductor (MOS) transistors that are provided in the semiconductor layer;
a passivation layer that is located above a top surface of the semiconductor layer and includes a plurality of openings;
a plurality of pads each of which is exposed to outside of the passivation layer in a corresponding one of the plurality of openings and functions as a terminal of one of the one or more vertical MOS transistors; and
a plurality of metal redistributions that are located above the top surface of the semiconductor layer and each of which is connected to one or more pads that are different from each other among the plurality of pads,
wherein in a plan view of the semiconductor device:
the passivation layer is contained within the semiconductor layer; and
each of the plurality of metal redistributions is contained within the semiconductor layer and contains the one or more pads connected to the metal redistribution,
the plurality of metal redistributions include a plurality of first metal redistributions each of which includes a first portion and a second portion contained within the first portion in the plan view, the second portion being located above the first portion and having an area smaller than an area of the first portion in the plan view,
each of the plurality of first metal redistributions includes one or more line-shaped bends in a boundary portion between the first portion and the second portion on a surface of the first metal redistribution, the one or more line-shaped bends each having an interior angle of at least 180 degrees in a cross section of the first metal redistribution,
in the plan view, the one or more line-shaped bends include a portion facing a peripheral side of the semiconductor device, and
a length of the second portion in a direction in which a normal line extends from the top surface of the semiconductor layer is greater than a length of the first portion in the direction.

2. The semiconductor device according to claim 1,
wherein a region having an angle of elevation of less than 90 degrees relative to the top surface of the semiconductor layer is located in a region of a lateral surface of the second portion, the region of the lateral surface of the second portion facing the peripheral side of the semiconductor device in the plan view.

3. The semiconductor device according to claim 1,
wherein a periphery of the passivation layer is located inward of a periphery of the semiconductor layer in the plan view, and
a lowermost surface of the first portion: is closer to the top surface of the semiconductor layer than the plurality of pads are in the direction; is contained within the semiconductor layer in the plan view; and is not contained within the periphery of the passivation layer in the plan view.

4. The semiconductor device according to claim 3,
wherein in the plan view:
a portion that is not contained within the periphery of the passivation layer is located on a periphery of the first portion; and
the second portion is contained within the periphery of the passivation layer.

5. The semiconductor device according to claim 1,
wherein each of the plurality of metal redistributions includes a multi-layer structure including: a first metal layer made of a first metal excluding gold; and a second metal layer made of a second metal including gold,
a first region flush with a lateral surface of the semiconductor layer is located in a lateral surface of the first portion in the plan view, and
the first metal is exposed in at least a portion of the first region.

6. The semiconductor device according to claim 1,
wherein each of the plurality of metal redistributions includes a multi-layer structure including: a first metal layer made of a first metal excluding gold; and a second metal layer made of a second metal including gold,
a lateral surface of the first portion is located inward of a lateral surface of the semiconductor layer in the plan view, and
the first metal is not exposed on an entirety of the lateral surface of the first portion, and the second metal is exposed on the entirety of the lateral surface of the first portion.

7. The semiconductor device according to claim 1,
wherein in the plan view:
the one or more line-shaped bends further include a portion facing a central side of the semiconductor device; and
a shortest distance between a peripheral portion of the first portion and the portion of the one or more line-shaped bends facing the peripheral side of the semiconductor device is longer than a shortest distance between the peripheral portion of the first portion and the portion of the one or more line-shaped bends facing the central side of the semiconductor device.

8. The semiconductor device according to claim 1,
wherein a total number of the plurality of metal redistributions is equal to a total number of the plurality of pads.

9. The semiconductor device according to claim 8,
wherein all of the plurality of metal redistributions are the plurality of first metal redistributions.

10. The semiconductor device according to claim 1,
wherein in the plan view:
the semiconductor layer is rectangular; and
the plurality of pads include: a first pad including no other pad between a first side of the semiconductor layer and a second side of the semiconductor layer that is orthogonal to the first side; a second pad including no other pad between the second side and a third side of the semiconductor layer that is orthogonal to the second side; a third pad including no other pad between the third side and a fourth side of the semiconductor layer that is orthogonal to the third side; and a fourth pad including no other pad between the fourth side and the first side, and
among the plurality of metal redistributions, each of a first specific metal redistribution connected to the first pad, a second specific metal redistribution connected to the second pad, a third specific metal redistribution connected to the third pad, and a fourth specific metal redistribution connected to the fourth pad is a different one of the plurality of first metal redistributions.

11. The semiconductor device according to claim 10,
wherein each of the first specific metal redistribution, the second specific metal redistribution, the third specific metal redistribution, and the fourth specific metal redistribution is connected to two or more pads among the plurality of pads.

12. The semiconductor device according to claim 10,
wherein among the plurality of pads, at least one of one or more specific pads excluding the first pad, the second pad, the third pad, and the fourth pad is connected to none of the plurality of metal redistributions.

13. The semiconductor device according to claim 10,
wherein among the plurality of pads, at least one of one or more specific pads excluding the first pad, the second pad, the third pad, and the fourth pad is connected to, among the plurality of metal redistributions, at least one of a plurality of second metal redistributions that are different from the plurality of first metal redistributions and each of which does not include the one or more line-shaped bends.

14. A semiconductor module comprising:
the semiconductor device according to claim 1; and
a mounting substrate on which the semiconductor device is face-down mounted,
wherein the mounting substrate includes a plurality of land patterns that correspond to the plurality of metal redistributions included in the semiconductor device on a one-to-one basis,
each of the plurality of land patterns is bonded, via a solder fillet including a solder bonding material, to one metal redistribution corresponding to the land pattern among the plurality of metal redistributions,
in the plan view:
an area of each of the plurality of land patterns is larger than an area of the one metal redistribution corresponding to the land pattern among the plurality of metal redistributions; and
each of the plurality of land patterns includes a portion that is not contained within the semiconductor device, and
the one or more line-shaped bends included in each of the plurality of first metal redistributions are filled with the solder fillet corresponding to the first metal redistribution.

15. A semiconductor module comprising:
the semiconductor device according to claim 10; and
a mounting substrate on which the semiconductor device is face-down mounted,
wherein the mounting substrate includes a plurality of land patterns that correspond to the plurality of metal redistributions included in the semiconductor device on a one-to-one basis,
each of the plurality of land patterns is bonded, via a solder fillet corresponding to the land pattern and including a solder bonding material, to one metal redistribution corresponding to the land pattern among the plurality of metal redistributions,
in the plan view:
an area of each of the plurality of land patterns is larger than an area of one metal redistribution corresponding to the land pattern among the plurality of metal redistributions; and
each of the plurality of land patterns includes a portion that is not contained within the semiconductor device,
the one or more line-shaped bends included in each of the plurality of first metal redistributions are filled with the solder fillet,
in the plan view:
among the plurality of land patterns, a first land pattern corresponding to the first specific metal redistribution includes: a region that extends beyond the first side to outside of the semiconductor device; and a region that extends beyond the second side to the outside of the semiconductor device;
among the plurality of land patterns, a second land pattern corresponding to the second specific metal redistribution includes: a region that extends beyond the second side to the outside of the semiconductor device; and a region that extends beyond the third side to the outside of the semiconductor device;
among the plurality of land patterns, a third land pattern corresponding to the third specific metal redistribution includes: a region that extends beyond the third side to the outside of the semiconductor device; and a region that extends beyond the fourth side to the outside of the semiconductor device; and
among the plurality of land patterns, a fourth land pattern corresponding to the fourth specific metal redistribution includes: a region that extends beyond the fourth side to the outside of the semiconductor device; and a region that extends beyond the first side to the outside of the semiconductor device.
